(19) United States
(12) Patent Application Publication
(10) Pub. No.: US 2025/0215361 A1
(43) Pub. Date: Jul. 3, 2025

(54) TREATMENT LIQUID FOR MANUFACTURING SEMICONDUCTOR, CLEANING METHOD OF OBJECT TO BE TREATED, AND MANUFACTURING METHOD OF SEMICONDUCTOR

(71) Applicant: FUJIFILM CORPORATION, Tokyo (JP)

(72) Inventor: Tetsuya Kamimura, Shizuoka (JP)

(21) Appl. No.: 19/082,439

(22) Filed: Mar. 18, 2025

Related U.S. Application Data
(63) Continuation of application No. PCT/JP2023/035113, filed on Sep. 27, 2023.

(30) Foreign Application Priority Data
Sep. 30, 2022 (JP) 2022-158779

(51) Int. Cl. C11D 7/26; C11D 7/32; H01L 21/02

(52) U.S. Cl. CPC C11D 7/265; C11D 7/3218; H01L 21/02065; C11D 2111/22

(57) ABSTRACT

The present invention provides a treatment liquid for manufacturing a semiconductor, in which, in a case where the treatment liquid is used for cleaning an object to be treated, containing at least one (specific material) selected from the group consisting of polysilicon, silicon carbide, and silicon carbonitride, defect removability on the specific material is excellent. The treatment liquid for manufacturing a semiconductor of the present invention contains a polycarboxylic acid and a polymer including a repeating unit A derived from a nonionic monomer and a repeating unit B having an anionic group.

### CROSS-REFERENCE TO RELATED APPLICATIONS

This application is a Continuation of PCT International Application No. PCT/JP2023/035113 filed on Sep. 27, 2023, which claims priority under 35 U.S.C. § 119 (a) to Japanese Patent Application No. 2022-158779 filed on Sep. 30, 2022. The above applications are hereby expressly incorporated by reference, in their entirety, into the present application.

### BACKGROUND OF THE INVENTION

### 1. Field of the Invention

The present invention relates to a treatment liquid for manufacturing a semiconductor, a cleaning method of an object to be treated, and a manufacturing method of a semiconductor.

### 2. Description of the Related Art

In development of a semiconductor device represented by a large-scale integrated circuit (LSI), there is a demand for higher density and higher integration through miniaturization and lamination of a wiring line in order to reduce size and increase speed. Under such a demand, in manufacture of a semiconductor device, a chemical mechanical polishing (CMP) treatment has been used for flattening a bare wafer, flattening an interlayer insulating film, forming a metal plug, forming an embedded wiring, and the like.

In the CMP treatment, residues of polishing fine particles, a polished wiring metal film, a metal component derived from a barrier metal, or the like used in the CMP treatment may remain on a surface of a semiconductor substrate after polishing. Therefore, after the CMP treatment, a treatment of removing these residues using a treatment liquid is generally performed.

In the manufacturing process of such a semiconductor device, there are various requirements for characteristics and formulations of members used in each of the above-described steps, depending on components and applications of an object to be treated.

Hereinafter, the treatment liquid used in the manufacturing process of the semiconductor device as described above is also referred to as “treatment liquid for manufacturing a semiconductor”.

For example, JP2022-009467A discloses a cleaning composition containing a predetermined organic acid, a fluoride compound, a polymer additive, and water.

### SUMMARY OF THE INVENTION

On the other hand, in recent years, a treatment liquid for use in an object to be treated, that contains at least one selected from the group consisting of polysilicon (poly-Si), silicon carbide (SiC), and silicon carbonitride (SiCN), which are generally used as an insulating film, has been required. In particular, a treatment liquid suitably used for cleaning the object to be treated after the CMP treatment, buffing the object to be treated after the CMP treatment, and the like has been required.

The present inventors have found that, in a case where the cleaning composition disclosed in JP2022-009467A is applied to cleaning of an object to be treated, containing at least one material (hereinafter, also simply referred to as “specific material”) selected from the group consisting of polysilicon, silicon carbide, and silicon carbonitride (particularly, an object to be treated after the CMP treatment, containing the specific material), further improvement is required in terms of defect removability on the specific material.

An object of the present invention is to provide a treatment liquid for manufacturing a semiconductor, in which, in a case where the treatment liquid is used for cleaning an object to be treated, containing at least one (specific material) selected from the group consisting of polysilicon, silicon carbide, and silicon carbonitride, defect removability on the specific material is excellent.

Another object of the present invention is to provide a cleaning method of an object to be treated and a manufacturing method of a semiconductor, which are related to the above-described treatment liquid for manufacturing a semiconductor.

As a result of conducting an extensive investigation to achieve the objects, the present inventors have found that the objects can be achieved by the following constitution.
[1] A treatment liquid for manufacturing a semiconductor, comprising:
a polycarboxylic acid; and
a polymer including a repeating unit A derived from a nonionic monomer and a repeating unit B having an anionic group.
[2] The treatment liquid for manufacturing a semiconductor according to [1],
in which the repeating unit A is a repeating unit represented by Formula (1) described later.
[3] The treatment liquid for manufacturing a semiconductor according to [2],
in which L¹ represents —COO— or —CO—NR^{a}—.
[4] The treatment liquid for manufacturing a semiconductor according to any one of [1] to [3],
in which a C log P of the nonionic monomer is-1.00 to 5.00.
[5] The treatment liquid for manufacturing a semiconductor according to any one of [1] to [4],
in which the repeating unit B is a repeating unit represented by Formula (2) described later.
[6] The treatment liquid for manufacturing a semiconductor according to any one of [1] to [5],
in which the anionic group is a carboxylic acid group, a sulfonic acid group, or a phosphonic acid group.
[7] The treatment liquid for manufacturing a semiconductor according to any one of [1] to [6],
in which the polycarboxylic acid has a hydroxyl group.
[8] The treatment liquid for manufacturing a semiconductor according to any one of [1] to [7],
in which a weight-average molecular weight of the polymer is 1,000 to 50,000.
[9] The treatment liquid for manufacturing a semiconductor according to any one of [1] to [8],
in which a mass ratio of a content of the polycarboxylic acid to a content of the polymer is 1 to 30.
[10] The treatment liquid for manufacturing a semiconductor according to any one of [1] to [9],
in which a pH is 2.0 to 10.0.
[11] The treatment liquid for manufacturing a semiconductor according to any one of [1] to [10], further comprising:
an amino alcohol.
[12] The treatment liquid for manufacturing a semiconductor according to [11],
in which the number of hydroxyl groups in the amino alcohol is 2 or more.
[13] The treatment liquid for manufacturing a semiconductor according to or [12],
in which a mass ratio of a content of the polymer to a content of the amino alcohol is 0.005 to 0.5.
[14] The treatment liquid for manufacturing a semiconductor according to any one of [1] to [13], further comprising:
an antibacterial agent.
[15] The treatment liquid for manufacturing a semiconductor according to [14],
in which a mass ratio of a content of the polymer to a content of the antibacterial agent is 5 to 100.
[16] The treatment liquid for manufacturing a semiconductor according to any one of [1] to [15],
in which the treatment liquid is used for an object to be treated, containing any of polysilicon, silicon carbide, or silicon carbonitride.
[17] A cleaning method of an object to be treated, comprising:
a step of cleaning an object to be treated, containing at least one selected from the group consisting of polysilicon, silicon carbide, and silicon carbonitride, with the treatment liquid for manufacturing a semiconductor according to any one of [1] to [15].
[18] A manufacturing method of a semiconductor, comprising:
the cleaning method of an object to be treated according to [17].

According to the present invention, it is possible to provide a treatment liquid for manufacturing a semiconductor, in which, in a case where the treatment liquid is used for cleaning an object to be treated, containing at least one (specific material) selected from the group consisting of polysilicon, silicon carbide, and silicon carbonitride, defect removability on the specific material is excellent.

In addition, according to the present invention, it is also possible to provide a cleaning method of an object to be treated and a manufacturing method of a semiconductor, which are related to the above-described treatment liquid for manufacturing a semiconductor.

### DESCRIPTION OF THE PREFERRED EMBODIMENTS

Hereinafter, the present invention will be described in detail.

The description of the configuration requirements described below is made on the basis of representative embodiments of the present invention, but it should not be construed that the present invention is limited to those embodiments.

Hereinafter, the meaning of each description in the present specification will be described.

Any numerical range expressed using “to” in the present specification refers to a range including the numerical values before and after the “to” as a lower limit value and an upper limit value, respectively.

The compounds described in the present specification may include, unless otherwise specified, isomers (compounds having the same number of atoms but having different structures), optical isomers, and isotopes thereof. In addition, only one kind or a plurality of kinds of the isomers and the isotopes may be included.

A bonding direction of a divalent group (for example, —COO—) denoted in the present specification is not limited unless otherwise specified. For example, in a case where Y in a compound represented by a formula “X—Y—Z” is —COO—, the compound may be “X—O—CO—Z” or “X—CO—O—Z”.

In the present specification, unless otherwise specified, a weight-average molecular weight (Mw) and a number-average molecular weight (Mn) are values converted using polystyrene as a standard substance, which are measured by a gel permeation chromatography (GPC) analyzer using TSKgel GMHxL, TSKgel G4000HxL, or TSKgel G2000HxL (all of which are product names manufactured by Tosoh Corporation) as a column, using tetrahydrofuran (THF) as an eluent, using a differential refractometer as a detector, and using polystyrene as a standard substance.

In the present specification, unless otherwise specified, a molecular weight of a compound having a molecular weight distribution is the weight-average molecular weight.

In the present specification, a primary amino group refers to a group represented by —NH₂; a secondary amino group refers to a group represented by —NHR^{T}; and a tertiary amino group refers to a group represented by-N(RT) 2.

R^{T}'s each independently represent an alkyl group which may have a substituent.

R^{T} in the secondary amino group may be bonded to a structure bonded to a bonding site of the secondary amino group to form a ring. In addition, two R^{T}'s in the tertiary amino group may be bonded to each other to form a ring. Here, in R^{T}, an atom directly bonded to a carbon atom having the bonding site with the nitrogen atom is a carbon atom or a hydrogen atom.

In the present specification, examples of a heteroatom include a nitrogen atom, a sulfur atom, an oxygen atom, a selenium atom, a tellurium atom, a phosphorus atom, a silicon atom, and a boron atom.

In the present specification, examples of a halogen atom include a fluorine atom, a chlorine atom, a bromine atom, and an iodine atom.

In the present specification, a C log P value is a value determined by calculating a common logarithm log P of a partition coefficient P of 1-octanol to water. A known method and software can be used as a method and software used for calculating the C log P value. In the present specification, unless otherwise specified, the C log P value is a value obtained by using a C log P program incorporated in ChemBioDraw Ultra 12.0 of CambridgeSoft Corporation.

### <Treatment Liquid>

The treatment liquid according to the embodiment of the present invention (hereinafter, also referred to as “present treatment liquid”) is a treatment liquid for manufacturing a semiconductor, containing a polycarboxylic acid and a polymer including a repeating unit A derived from a nonionic monomer and a repeating unit B having an anionic group (hereinafter, also referred to as “specific polymer”).

Although the mechanism by which the object of the present invention can be achieved by adopting the above-described configuration of the present treatment liquid is not clear, the present inventors presume as follows.

At least one kind (specific material) selected from the group consisting of polysilicon, silicon carbide, and silicon carbonitride, which are materials used as a semiconductor substrate material (for example, a gate electrode), has a property that a surface thereof exhibits relatively hydrophobicity, as compared with other general-purpose materials such as silicon dioxide and silicon nitride.

Therefore, an organic residue exhibiting hydrophobic properties is likely to remain on a surface of the specific material. In addition, since the specific material is likely to be polished, the specific material is generally subjected to a CMP treatment after the surface is protected with a surfactant or the like, and thus the surfactant is likely to remain as an organic residue.

In addition, in a case where a cleaning is carried out after the CMP treatment using the cleaning composition disclosed in JP2022-009467A, defect removability on the surface of the specific material is insufficient because the composition containing water as a main component, which is generally used after the CMP treatment, had poor affinity with the surface of the specific material.

On the other hand, in the present treatment liquid, since the specific polymer includes the repeating unit A derived from a nonionic monomer and the repeating unit B having an anionic group, it is considered that the group in the repeating unit A interacts with the organic residues (defects) on the surface of the specific material, while the anionic group functions to be separated from the surface of the specific material, and as a result, the defects can be efficiently removed.

Hereinafter, components contained in the present treatment liquid will be described in detail. In the following, in a case where the present treatment liquid is used for cleaning an object to be treated containing the specific material, the fact that the defect removability on the specific material is more excellent is also referred to as “effect of the present invention is more excellent”.

### [Polycarboxylic Acid]

The present treatment liquid contains a polycarboxylic acid. The polycarboxylic acid is a compound having two or more carboxylic acid groups (carboxy groups) in one molecule.

The polycarboxylic acid is a compound different from the specific polymer described later, and is a compound not including a repeating unit.

The number of carboxy groups in the polycarboxylic acid is not particularly limited as long as it is 2 or more, and it is preferably 2 to 10, more preferably 2 to 5, and still more preferably 2 or 3.

A molecular weight of the polycarboxylic acid is not particularly limited, but is preferably 50 to 750, more preferably 50 to 500, and still more preferably 100 to 350.

The above-described polycarboxylic acid may be any of an aliphatic polycarboxylic acid or an aromatic polycarboxylic acid. The aliphatic polycarboxylic acid is a polycarboxylic acid having no aromatic ring in the molecule; and the aromatic polycarboxylic acid is a polycarboxylic acid having an aromatic ring in the molecule. The aliphatic polycarboxylic acid may have an alicyclic structure.

In addition, the polycarboxylic acid may have a substituent other than the carboxy group.

The substituent included in the polycarboxylic acid is preferably a hydroxyl group. That is, the polycarboxylic acid may be a hydroxy polycarboxylic acid. The number of hydroxyl groups in the polycarboxylic acid is preferably 1 to 6, more preferably 1 to 3, and still more preferably 1 or 2.

The polycarboxylic acid is preferably a compound represented by Formula (X1).

L^{a}-(COOH)ₙₐ (X1)

In Formula (X1), L^{a} represents a single bond or an na-valent aliphatic hydrocarbon group which may have a substituent. na represents an integer of 2 or more.

From the viewpoint that the effect of the present invention is more excellent, na is preferable 2 to 5 and more preferable 2 or 3.

The na-valent aliphatic hydrocarbon group is a group obtained by removing na pieces of hydrogen atoms from an aliphatic hydrocarbon.

The na-valent aliphatic hydrocarbon group may be linear, branched, or cyclic, and may have an unsaturated bond in the molecule.

The number of carbon atoms (the number of carbon atoms excluding the above-described substituent) in the na-valent aliphatic hydrocarbon group is not particularly limited, but from the viewpoint that the effect of the present invention is more excellent, it is preferably 2 to 10, more preferably 2 to 6, and still more preferably 2 or 3.

As the na-valent aliphatic hydrocarbon group, a group obtained by removing two or three hydrogen atoms from an aliphatic saturated hydrocarbon is preferable.

The na-valent aliphatic hydrocarbon group may have a substituent. The number of substituents which may be included in the na-valent aliphatic hydrocarbon group is not particularly limited, but is preferably 1 to 3 and more preferably 1 or 2.

Examples of the substituent which may be included in the na-valent aliphatic hydrocarbon group include a hydroxyl group, a halogen atom, and an alkyloxycarbonyl group; and among these, a hydroxyl group is preferable.

In Formula (X1), examples of a polycarboxylic acid in which na is 2 (dicarboxylic acid) include oxalic acid, malonic acid, succinic acid, glutaric acid, adipic acid, pimelic acid, suberic acid, azelaic acid, sebacic acid, undecanedioic acid, dodecanedioic acid, eicosanedioic acid, eicosadienoic acid, cyclopentanedicarboxylic acid, cyclopentenedicarboxylic acid, cyclohexanedicarboxylic acid, cyclohexenedicarboxylic acid, octane-4,5-dicarboxylic acid, nonane-1,3-dicarboxylic acid, 2-butyloctanoic acid, tartronic acid, malic acid, and tartaric acid.

From the viewpoint that the effect of the present invention is more excellent, the dicarboxylic acid is preferably malonic acid, succinic acid, malic acid, or tartaric acid, and more preferably malic acid or tartaric acid.

In Formula (X1), examples of a polycarboxylic acid in which na is 3 (tricarboxylic acid) include 1α,3α,5β-cyclohexanetricarboxylic acid, 1,2,4-butanetricarboxylic acid, and citric acid.

From the viewpoint that the effect of the present invention is more excellent, the tricarboxylic acid is preferably citric acid.

A content of the polycarboxylic acid is preferably 12.5 ppm by mass or more, more preferably 50.0 ppm by mass or more, and still more preferably 150.0 ppm by mass with respect to the total mass of the treatment liquid.

The upper limit thereof is preferably 25.0% by mass or less, more preferably 10.0% by mass or less, and still more preferably 5.0% by mass or less.

In addition, the content of the polycarboxylic acid is preferably 1.0% by mass or more, more preferably 5.0% by mass or more, and still more preferably 20.0% by mass or more with respect to the total mass of components of the treatment liquid, excluding a solvent. The upper limit thereof is not particularly limited, but is preferably 80.0% by mass or less and more preferably 70.0% by mass or less.

In addition, from the viewpoint that the effect of the present invention is more excellent, a mass ratio of the content of the polycarboxylic acid to a content of the specific polymer, which will be described later, is preferably 0.2 to 150, more preferably 0.2 to 50, still more preferably 1 to 50, and particularly preferably 1 to 30.

The polycarboxylic acid may be used alone or in combination of two or more kinds thereof. In a case where two or more kinds of polycarboxylic acids are used, it is also preferable that the total content thereof is within the above-described preferred range.

### [Specific Polymer]

The present treatment liquid contains a polymer (specific polymer) including a repeating unit A derived from a nonionic monomer and a repeating unit B having an anionic group.

### (Repeating Unit A)

The repeating unit A is a repeating unit derived from a nonionic monomer.

In the present specification, the nonionic monomer means a monomer which does not ionize even in a case of being dissolved in water. In other words, the nonionic monomer is a monomer having no group to be ionized. In the present specification, a group represented by —CO—NH₂ is treated as the nonionic group.

The nonionic monomer may be hydrophilic or hydrophobic, but is preferably hydrophobic. In addition, the nonionic monomer may include a heteroatom, and examples of the heteroatom include an oxygen atom, a nitrogen atom, and a sulfur atom.

The nonionic group in the nonionic monomer is not particularly limited, and examples thereof include a hydrocarbon group, a cyano group, —CO—N(R^{a})(X¹), and a group including a polymer chain described later. R^{a} and X¹ are as described later.

A methylene group in the above-described hydrocarbon group may be substituted with —CO— or —O—.

The nonionic monomer preferably has a hydrocarbon group.

As the hydrocarbon group, an aliphatic hydrocarbon group or an aromatic hydrocarbon group is preferable, and an aliphatic hydrocarbon group is more preferable.

The number of carbon atoms in the aliphatic hydrocarbon group is not particularly limited, but is preferably 1 to 10 and more preferably 1 to 4.

The aliphatic hydrocarbon group may be linear, branched, or cyclic.

The aromatic hydrocarbon group may be monocyclic or polycyclic.

The number of carbon atoms in the aromatic hydrocarbon group is not particularly limited, but is preferably 6 to 18 and more preferably 6 to 12.

A methylene group in the above-described hydrocarbon group may be substituted with —CO— or —O—.

In addition, it is also preferable that the nonionic monomer has a polymer chain.

The polymer chain is a structure including a plurality of repeating units.

It is sufficient that the polymer chain is nonionic, and for example, a polymer chain having at least one structure selected from the group consisting of a polyester structure, a poly(meth)acrylic structure, a polystyrene structure, a polyurethane structure, and a polyether structure is preferable. Among these, a polymer chain having a polyester structure is preferable.

Examples of the polyester structure include a polycaprolactone structure and a polyvalerolactone structure.

The polycaprolactone structure refers to a structure including, as a repeating unit, a structure obtained by ring-opening ε-caprolactone; and the polyvalerolactone structure refers to a structure including, as a repeating unit, a structure obtained by ring-opening δ-valerolactone.

From the viewpoint that the effect of the present invention is more excellent, the repeating unit A is preferably a repeating unit represented by Formula (1).

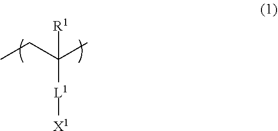

In Formula (1), R¹ represents a hydrogen atom or an alkyl group,
L¹ represents a single bond, —COO—, or —CO—NR^{a}—, and
X¹ represents a hydrogen atom, a hydrocarbon group, or a group including a polymer chain, where a methylene group in the hydrocarbon group may be substituted with —CO— or —O—, provided that, in a case where X¹ is a hydrogen atom, L¹ represents —CO—NR^{a}—, and R^{a} represents a hydrogen atom or an alkyl group.

The alkyl group represented by R¹ may be linear, branched, or cyclic, but is preferably linear. The number of carbon atoms in the above-described alkyl group is preferably 1 to 10, more preferably 1 to 6, and still more preferably 1 or 2.

Among these, R¹ is preferably a hydrogen atom or a methyl group.

L¹ represents a single bond, —COO—, or —CO—NR^{a}—. Among these, from the viewpoint that the effect of the present invention is more excellent, —COO— or —CO—NR^{a}— is preferable.

R^{a} represents a hydrogen atom or an alkyl group.

The number of carbon atoms in the alkyl group represented by R^{a} is not particularly limited, but is preferably 1 to 10, more preferably 1 to 6, and still more preferably 1 or 2.

X¹ represents a hydrogen atom, a hydrocarbon group, or a group including a polymer chain. A methylene group in the hydrocarbon group may be substituted with —CO— or —O—.

A suitable aspect of the hydrocarbon group represented by X¹ is the same as the suitable aspect of the hydrocarbon group which may be included in the nonionic monomer described above.

A suitable aspect of the group including a polymer chain, represented by X¹, is the same as the suitable aspect of the group including a polymer chain, which may be included in the nonionic monomer described above.

In a case where X¹ is a hydrogen atom, L¹ represents —CO—NR^{a}—.

In addition, in a case where the nonionic monomer has a polymer chain as described above, examples of the repeating unit A include a repeating unit represented by Formula (1-1) or a repeating unit represented by Formula (1-2).

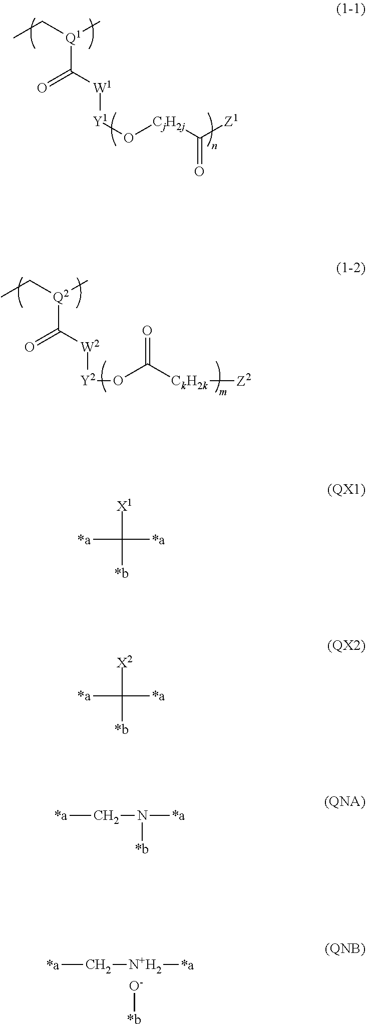

In Formula (1-1) or Formula (1-2), Q¹ is a group represented by any of Formula (QX1), Formula (QNA), or Formula (QNB), and Q² is a group represented by any of Formula (QX2), Formula (QNA), or Formula (QNB).

In Formula (QX1), Formula (QX2), Formula (QNA), and Formula (QNB), *a represents a bonding position on the main chain side, and *b represents a bonding position on the side chain side.

In Formula (1-1) and Formula (1-2), W¹ and W² each independently represent a single bond, an oxygen atom, or NH.

In Formula (QX1) and Formula (QX2), X¹ and X² each independently represent a hydrogen atom or a monovalent organic group; and are preferably a hydrogen atom or an alkyl group having 1 to 12 carbon atoms, and more preferably a hydrogen atom or a methyl group.

In Formula (1-1) or Formula (1-2), Y¹ and Y² each independently represent a single bond or a divalent linking group; and examples of the divalent linking group include linking groups represented by Formulae (Y-1) to (Y-23).

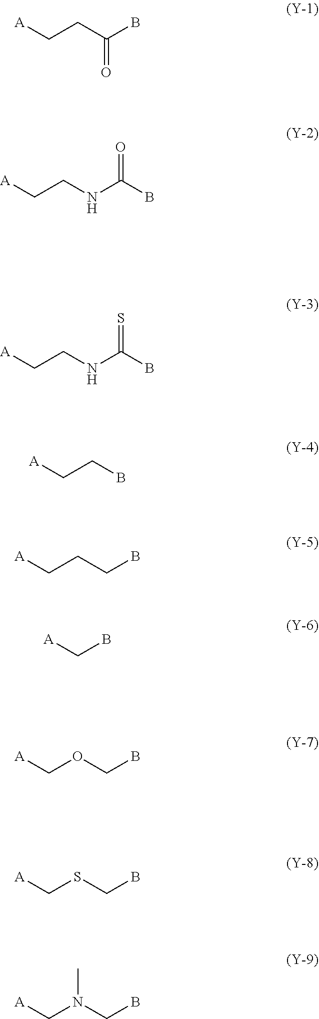

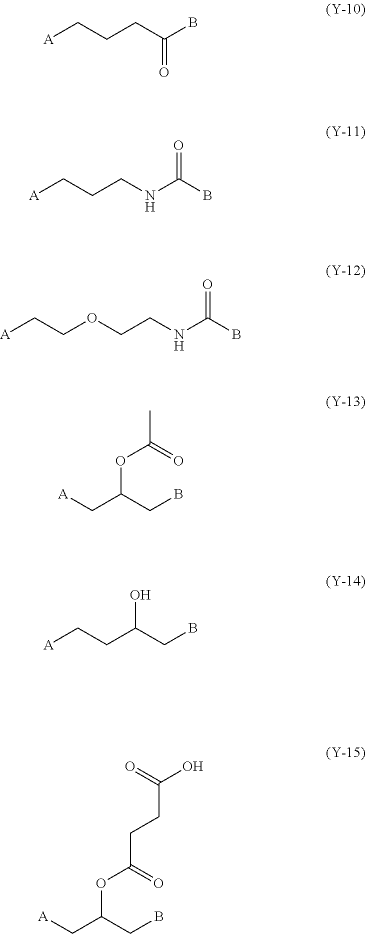

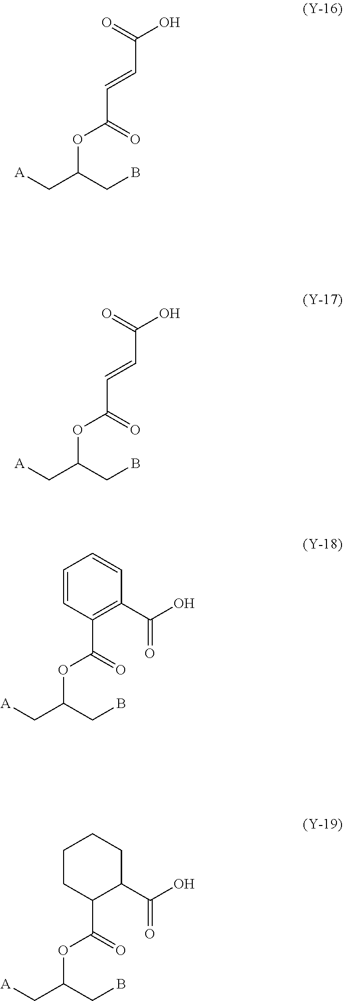

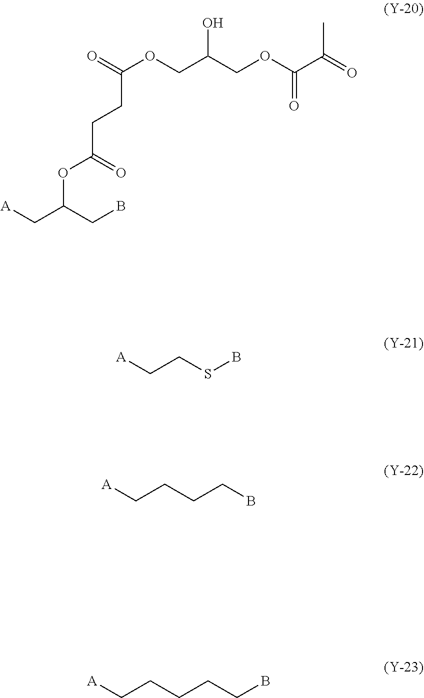

In Formulae (Y-1) to (Y-23), A represents a bonding position to W¹ or W² in Formula (1-1) or Formula (1-2). B represents a bonding position to a group on a side opposite to W¹ or W² to which A is bonded.

In Formula (1-1) and Formula (1-2), Z¹ and Z² each independently represent a hydrogen atom or a monovalent organic group.

A structure of the above-described monovalent organic group is not particularly limited, but specific examples thereof include a hydroxy group, an acyloxy group (—O(C═O)R), an alkyl group, an alkoxy group, an aryloxy group, a heteroaryloxy group, an alkylthioether group, an arylthioether group, a heteroarylthioether group, a primary amino group, a secondary amino group, and a tertiary amino group.

The acyloxy group, the alkyl group, and the alkoxy group described above may be linear, branched, or cyclic, and may further have a substituent. Examples of the above-described substituent include a hydroxy group.

The number of carbon atoms in the above-described monovalent organic group is preferably 5 to 24, more preferably 6 to 20, and still more preferably 6 to 10.

Among these, as the monovalent organic group represented by Z¹ and Z², an acryloyl group, a hydroxy group, an acyloxy group, or an alkoxy group is preferable.

In Formula (1-1) and Formula (1-2), n and m each independently represent 2 to 20. In particular, 2 to 10 is preferable.

In addition, in Formula (1-1) and Formula (1-2), j and k each independently represent an integer of 2 to 8; and among these, an integer of 4 to 6 is preferable and 5 is more preferable.

From the viewpoint that the effect of the present invention is more excellent, a C log P of the nonionic monomer is preferably-1.00 to 5.00, more preferably 0.50 to 5.00, still more preferably 1.00 to 5.00, and particularly preferably 0.50 to 3.00.

Specific examples of the nonionic monomer include methyl acrylate, ethyl acrylate, butyl acrylate, 2-ethylhexyl acrylate, N,N-dimethylacrylamide, diacetone acrylamide, and acrylamide.

A content of the repeating unit A in the specific polymer is preferably 20 to 80 mol %, more preferably 25 to 70 mol %, and still more preferably 30 to 60 mol % with respect to all repeating units of the specific polymer.

The specific polymer may include two or more kinds of the repeating units A, and in this case, the total content of all the repeating units A is preferably within the above-described range.

### (Repeating Unit B)

The repeating unit B has an anionic group.

The anionic group is not particularly limited as long as it is a group which is to be an anion in water; but among these, an acid group is preferable, and a carboxylic acid group, a sulfonic acid group, or a phosphonic acid group is more preferable.

The number of anionic groups in the repeating unit B is not particularly limited, but is preferably 1 to 4, more preferably 1 to 3, and still more preferably 1 or 2.

From the viewpoint that the effect of the present invention is more excellent, the repeating unit B is preferably a repeating unit represented by Formula (2).

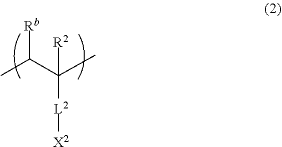

In Formula (2), Rb represents a hydrogen atom or an anionic group,

R² represents a hydrogen atom or an alkyl group,

L² represents a single bond or a divalent linking group, and

X² represents an anionic group.

Specific aspects and preferred aspects of the anionic group represented by Rb are the same as the specific aspects and preferred aspects of the anionic group described above.

In addition, specific aspects and preferred aspects of the anionic group represented by X² are also the same as the specific aspects and preferred aspects of the anionic group described above.

The alkyl group represented by R² may be linear, branched, or cyclic, but is preferably linear. The number of carbon atoms in the above-described alkyl group is preferably 1 to 10, more preferably 1 to 6, and still more preferably 1 or 2.

Among these, R² is preferably a hydrogen atom or a methyl group.

Examples of the divalent linking group represented by L² include an alkylene group, an arylene group, —O—, —CO—, —NH—, —NR^{N2}— (R^{N2} represents an alkyl group having 1 to 6 carbon atoms), and a divalent linking group formed by a combination thereof.

The divalent linking group represented by L² may have a substituent, and examples of the substituent include a hydroxyl group and a halogen atom.

The number of carbon atoms in the divalent linking group represented by L² is preferably 1 to 10, more preferably 1 to 6, and still more preferably 1 or 2.

The alkylene group represented by L² may be linear, branched, or cyclic. The number of carbon atoms in the alkylene group represented by L² is preferably 1 to 10, more preferably 1 to 6, and still more preferably 1 to 3.

Examples of the divalent alkylene group represented by L² include a methylene group, an ethylene group, and a propylene group.

The arylene group represented by L² is preferably a phenylene group.

A content of the repeating unit B in the specific polymer is preferably 20 to 80 mol %, more preferably 30 to 75 mol %, and still more preferably 40 to 70 mol % with respect to all repeating units of the specific polymer.

The specific polymer may include two or more kinds of the repeating units B, and in this case, the total content of all the repeating units B is preferably within the above-described range.

A ratio of the repeating unit A and the repeating unit B in the specific polymer is not particularly limited, but from the viewpoint that the effect of the present invention is more excellent, a ratio a/b of the number of moles a of the repeating unit A to the number of moles b of the repeating unit B is preferably 1/99 or more, more preferably 5/95 or more, still more preferably 10/90 or more, and particularly preferably 25/75 or more.

The upper limit of the ratio a/b is not particularly limited, but the ratio a/b is preferably 70/30 or less, more preferably 65/35 or less, still more preferably 60/40 or less, and particularly preferably 55/45 or less.

In the specific polymer, the repeating unit A and the repeating unit B may be randomly bonded (so-called random copolymer), may be alternately bonded (so-called alternating copolymer), or may be bonded in a block manner (so-called block copolymer).

The specific polymer may have a repeating unit different from both the repeating unit A and the repeating unit B.

A content of the repeating unit different from both the repeating unit A and the repeating unit B in the specific polymer is preferably 20 mol % or less, more preferably 0 to 10 mol %, and still more preferably 0 to 5 mol % with respect to all repeating units in the specific polymer.

It is preferable that the specific polymer does not have a repeating unit different from both the repeating unit A and the repeating unit B.

A weight-average molecular weight of the specific polymer is preferably 800 to 75,000, more preferably 1,000 to 50,000, and still more preferably 1,000 to 20,000.

An acid value of the specific polymer is preferably 200 mgKOH/g or less, more preferably 150 mgKOH/g or less, and still more preferably 120 mgKOH/g or less. The lower limit thereof is preferably 5 mgKOH/g or more.

A content of the specific polymer is preferably 0.1 ppm by mass or more, more preferably 15.0 ppm by mass or more, and still more preferably 50.0 ppm by mass or more with respect to the total mass of the treatment liquid.

The upper limit thereof is preferably 10.0% by mass or less, more preferably 5.0% by mass or less, and still more preferably 1.0% by mass or less.

In addition, the content of the specific polymer is preferably 0.10% by mass or more, more preferably 0.45% by mass or more, still more preferably 0.80% by mass or more, and particularly preferably 3.00% by mass or more with respect to the total mass of components of the treatment liquid, excluding a solvent. The upper limit thereof is not particularly limited, but is preferably 60.0% by mass or less, more preferably 40.0% by mass or less, and still more preferably 20.0% by mass or less.

In addition, a mass ratio of the content of the polymer to a content of an amino alcohol described later is preferably 0.001 to 2.0, more preferably 0.005 to 1.0, and still more preferably 0.005 to 0.5.

In addition, a mass ratio of the content of the polymer to a content of an antibacterial agent described later is preferably 0.1 to 200, more preferably 1 to 100, still more preferably 0.3 to 90.0, particularly preferably 1.0 to 50.0, and most preferably 1.0 to 20.0.

The specific polymer may be used alone or in combination of two or more kinds thereof. In a case where two or more kinds of specific polymers are used, it is also preferable that the total content thereof is within the above-described preferred range.

### [Optional Component]

The present treatment liquid may contain an optional component other than the above-described components. Hereinafter, the optional component will be described in detail.

### (Amino Alcohol)

From the viewpoint that the effect of the present invention is more excellent, the present treatment liquid preferably contains an amino alcohol.

The amino alcohol refers to an organic compound having at least one group selected from the group consisting of a primary amino group, a secondary amino group, and a tertiary amino group, and a hydroxyl group in the molecule.

The number of at least one group selected from the group consisting of a primary amino group, a secondary amino group, and a tertiary amino group, which is included in the amino alcohol, is not particularly limited, but for example, it is preferably 1 to 4, more preferably 1 or 2, and still more preferably 1.

From the viewpoint that the effect of the present invention is more excellent, the number of hydroxyl groups in the amino alcohol is preferably 2 or more and more preferably 3 or more. The upper limit thereof is not particularly limited, but for example, it is preferably 10 or less, and more preferably 8 or less.

As the amino alcohol, a compound represented by Formula (A1) or Formula (A2) is preferable.

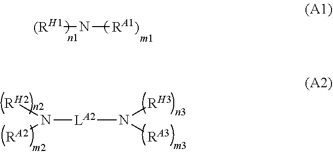

In Formula (A1), R^{A1}'s each independently represent a hydrogen atom or an alkyl group. The number of carbon atoms in the alkyl group represented by R^{A1} is preferably 1 to 3 and more preferably 1 or 2.

In Formula (A1), R^{H1}'s each independently represent an alkyl group having at least one or more hydroxyl groups. The number of carbon atoms in the alkyl group having at least one hydroxyl group, represented by R^{H1}, is preferably 1 to 6 and more preferably 2 to 4.

The number of hydroxyl groups in the alkyl group having at least one hydroxyl group, represented by R^{H1}, is preferably 1 to 6 and more preferably 1 to 3.

Examples of the group represented by R^{H1} include a hydroxymethyl group, a 1-hydroxyethyl group, a 2-hydroxyethyl group, a 3-hydroxypropyl group, a 2,3-dihydroxypropyl group, a bis(hydroxymethyl) methyl group, a tris (hydroxymethyl) methyl group, and a 2,3,4,5,6-pentahydroxyhexyl group.

In Formula (A1), n1 represents an integer of 1 to 3, and m1 represents an integer of 0 to 2. Here, n1 and m1 are selected such that the sum of n1 and m1 is 3. n1 is preferably 1 or 2. m1 is preferably 1 or 2.

Examples of the compound represented by Formula (A1) include monoethanolamine, diethanolamine, triethanolamine, N-methyldiethanolamine, N-ethyldiethanolamine, trishydroxymethylaminomethane (also referred to as Tris), bis(2-hydroxyethyl)aminotrist(hydroxymethyl)methane (also referred to as Bis-Tris), glucamine, and N-methylglucamine.

In Formula (A2), R^{A2} and R^{A3} each independently represent a hydrogen atom or an alkyl group. Since preferred aspects of the groups represented by R^{A2} and R^{A3} are the same as the preferred aspects of the group represented by R^{A1}, description thereof will not be repeated.

In Formula (A2), R^{H2} and R^{H3} each independently represent an alkyl group having at least one or more hydroxyl groups. Since preferred aspects of the groups represented by R^{H2} and R^{H3} are the same as the preferred aspects of the group represented by R^{H1}, description thereof will not be repeated.

In Formula (A2), n2 represents an integer of 1 or 2, and m2 represents an integer of 0 or 1. Here, n2 and m2 are selected such that the sum of n2 and m2 is 2.

In Formula (A2), n3 represents an integer of 1 or 2, and m3 represents an integer of 0 or 1. Here, n3 and m3 are selected such that the sum of n3 and m3 is 2.

In Formula (A2), L^{A2} represents a divalent linking group. L^{A2} preferably represents an alkylene group having 1 to 6 carbon atoms.

Examples of the compound represented by Formula (A2) include 1,3-bis[tris(hydroxymethyl)methylamino]propane (also referred to as bis-trispropane).

Among these, as the amino alcohol, trishydroxymethylaminomethane, bis(2-hydroxyethyl)aminotrist(hydroxymethyl)methane, or 1,3-bis[tris(hydroxymethyl)methylamino]propane is preferable.

A content of the amino alcohol is preferably 15.0 ppm by mass or more, more preferably 150 ppm by mass or more, and still more preferably 500 ppm by mass or more with respect to the total mass of the treatment liquid.

The upper limit thereof is preferably 20.0% by mass or less, more preferably 15.0% by mass or less, and still more preferably 5.0% by mass or less.

In addition, the content of the amino alcohol is preferably 10.0% by mass or more, and more preferably 25.0% by mass or more with respect to the total mass of components of the treatment liquid, excluding a solvent. The upper limit thereof is not particularly limited, but is preferably 90.0% by mass or less and more preferably 70.0% by mass or less.

The amino alcohol may be used alone or in combination of two or more kinds thereof. In a case where two or more kinds of amino alcohols are used, it is also preferable that the total content thereof is within the above-described preferred range.

### (Antibacterial Agent)

From the viewpoint that the effect of the present invention is more excellent, the present treatment liquid preferably contains an antibacterial agent.

The antibacterial agent refers to a compound capable of suppressing proliferation of microorganisms, and is a compound different from the above-described polycarboxylic acid and the above-described specific polymer.

A molecular weight of the antibacterial agent is preferably 50 to 700, more preferably 100 to 600, and still more preferably 100 to 500.

Examples of the antibacterial agent include a cationic antibacterial agent (such as a quaternary ammonium-based antibacterial agent), a carboxylic acid-based antibacterial agent, a phenol-based antibacterial agent, an isothiazolinone-based antibacterial agent, a biguanide-based antibacterial agent, a sulfamide-based antibacterial agent, a peroxide-based antibacterial agent, an imidazole-based antibacterial agent, an ester-based antibacterial agent, an alcohol-based antibacterial agent, a carbamate-based antibacterial agent, an iodine-based antibacterial agent, and antibiotics.

Examples of the quaternary ammonium-based antibacterial agent include benzalkonium chloride, didecyldimethylammonium chloride (DDAC), hexadecylpyridinium chloride (CPC), 3,3′-(2,7-dioxaoctane)bis(1-dodecylpyridinium bromide) (Hyjeria), benzethonium chloride, and domiphen bromide.

Among these, benzethonium chloride is preferable.

Examples of the carboxylic acid-based antibacterial agent include sorbic acid, dehydroacetic acid, benzoic acid, and salicylic acid; and sorbic acid, benzoic acid, or salicylic acid is preferable.

Examples of the phenolic antibacterial agent include cresol, catechol, chlorothymol, dichloroxylenol, and hexachlorophene.

Examples of the isothiazolinone-based antibacterial agent include 2-methyl-4-isothiazolin-3-one (MIT), 2-octyl-4-isothiazolin-3-one (OIT), 1,2-benzisothiazol-3 (2H)-one (BIT), and 5-chloro-2-methyl-4-isothiazolin-3-one (CIT).

Among these, MIT, OIT, or BIT is preferable, and MIT or OIT is more preferable.

Examples of the imidazole-based antibacterial agent include 2-(4-thiazolyl)-benzimidazole (TBZ) and methyl 2-benzimidazolecarbamate (PREVENTOL BCM).

Examples of the biguanide-based antibacterial agent include bis(p-chlorophenyldiguanide)hexanedigluconate (chlorhexidine gluconate) and poly(hexamethylene biguanide)hydrochloride (hexamethylene biguanidine hydrochloride). Among these, chlorhexidine gluconate is preferable.

A content of the antibacterial agent is preferably 0.1 ppm by mass or more, more preferably 1.5 ppm by mass or more, and still more preferably 5.0 ppm by mass or more with respect to the total mass of the treatment liquid.

The upper limit thereof is preferably 2.0% by mass or less and more preferably 1.0% by mass or less.

Among these, from the viewpoint of excellent defect removability on silicon nitride, the content of the antibacterial agent with respect to the total mass of the treatment liquid is preferably 0.5 to 12.5 ppm by mass.

In addition, the content of the antibacterial agent is preferably 0.01% by mass or more, more preferably 0.1% by mass or more, and still more preferably 0.5% by mass or more with respect to the total mass of components of the treatment liquid, excluding a solvent. The upper limit thereof is not particularly limited, but is preferably 15.0% by mass or less, more preferably 4.0% by mass or less, and still more preferably 1.0% by mass or less.

Among these, from the viewpoint of excellent defect removability on silicon nitride, the content of the antibacterial agent with respect to the total mass of components of the treatment liquid, excluding a solvent, is preferably 0.1% to 4.0% by mass.

The antibacterial agent may be used alone or in combination of two or more kinds thereof. In a case where two or more kinds of antibacterial agents are used, it is also preferable that the total content thereof is within the above-described preferred range.

### (Solvent)

The present treatment liquid preferably contains a solvent.

Examples of the solvent include water and an organic solvent.

It is preferable that the organic solvent is mixed with water at an optional ratio.

Examples of the organic solvent include an alcohol-based solvent, a glycol-based solvent, a glycol ether-based solvent, a ketone-based solvent, and a sulfur-containing solvent.

As the organic solvent, for example, compounds exemplified in paragraphs [0135] to [0140] of WO2022/044893A can also be used, the contents of which are incorporated herein by reference.

The solvent is preferably water. As the water, distilled water, deionized water, pure water, or ultrapure water is preferable, and pure water or ultrapure water is more preferable.

A content of the solvent is preferably 70.0% by mass or more, more preferably 80.0% by mass or more, and still more preferably 90.0% by mass or more with respect to the total mass of the treatment liquid.

The upper limit thereof is preferably 99.999% by mass or less, more preferably 99.97% by mass or less, and still more preferably 99.7% by mass or less.

The solvent may be used alone or in combination of two or more kinds thereof. In a case where two or more kinds of solvents are used, it is also preferable that the total content thereof is within the above-described preferred range.

### (pH Adjuster)

The present treatment liquid may contain a pH adjusting agent. A pH of the treatment liquid may be adjusted to a preferred pH range described later by the pH adjusting agent.

It is preferable that the pH adjuster is a compound different from the above-described compounds. Examples of the pH adjuster include an acidic compound and a basic compound.

The acidic compound is an acidic compound which exhibits acidity (a pH of less than 7.0) in an aqueous solution.

Examples of the acidic compound include an inorganic acid and a salt thereof.

Examples of the inorganic acid include sulfuric acid, hydrochloric acid, nitric acid, phosphoric acid, and salts thereof.

A content of the acidic compound is preferably 0.1% to 10.0% by mass, and more preferably 0.3% to 5.0% by mass with respect to the total mass of the treatment liquid.

The basic compound is a compound which exhibits alkalinity (a pH of more than 7.0) in an aqueous solution.

Examples of the basic compound include an organic base, an inorganic base, and a salt thereof.

Examples of the inorganic base include alkali metal hydroxides such as sodium hydroxide and potassium hydroxide, alkaline earth metal hydroxides, and ammonia.

Examples of the organic base include a quaternary ammonium salt. An anion contained in the quaternary ammonium salt is preferably Cl⁻, Br⁻, or OH⁻, more preferably Cl⁻ or OH⁻, and still more preferably OH⁻.

A content of the basic compound is preferably 0.1% to 10.0% by mass, and more preferably 0.3% to 5.0% by mass with respect to the total mass of the treatment liquid.

The present treatment liquid may contain an oxidizing agent, a surfactant, or the like, in addition to the above-described components.

### <Properties of Treatment Liquid>

Preferred properties of the treatment liquid according to the embodiment of the present invention will be described.

[pH]

A pH of the treatment liquid according to the embodiment of the present invention is preferably 1.0 to 12.0, more preferably 2.0 to 10.0, and still more preferably 3.0 to 8.0.

It is considered that the removability of defects derived from residues is more excellent by setting the pH of the treatment liquid to the above-described preferred range.

The pH of the treatment liquid can be measured by a method based on JIS Z8802-1984 using a known pH meter. The measurement temperature is set to 25° C.

### [Insoluble Particles]

It is preferable that the treatment liquid according to the embodiment of the present invention substantially does not contain insoluble particles.

The “insoluble particles” are particles of an inorganic solid, an organic solid, and the like, and correspond to particles which are present as particles without being finally dissolved in the treatment liquid.

The expression “does not substantially contain insoluble particles” means that the number of particles having a particle diameter of 50 nm or more, contained in 1 mL of a composition for measurement, is 40,000 or less in a case where the treatment liquid is diluted 10,000 times with the solvent contained in the treatment liquid to obtain the composition for measurement. The number of the particles contained in the composition for measurement can be measured in a liquid phase using a commercially available particle counter.

As a commercially available particle counter device, a device manufactured by RION Co., Ltd. or a device manufactured by PMS Co., Ltd. can be used. Representative examples of the device of the former include KS-19F, and representative examples of the device of the latter include Chem20. In order to measure larger coarse particles, a device such as KS-42 series or LiQuilaz II S series can be used.

Examples of the insoluble particles include inorganic solids such as silica (including colloidal silica and fumed silica), alumina, zirconia, ceria, titania, germania, manganese oxide, and silicon carbide; and organic solids such as polystyrene, a polyacrylic resin, and polyvinyl chloride.

Examples of a method for removing the insoluble particles from the treatment liquid include a purification treatment such as filtering.

### [Coarse Particles]

The treatment liquid according to the embodiment of the present invention may contain coarse particles, but it is preferable that a content thereof is low.

The coarse particles mean particles having a diameter (particle size) of 1 μm or more, in a case where a shape of the particles is regarded as a sphere. The particles included in the above-described insoluble particles may be included in the coarse particles.

A content of the coarse particles in the treatment liquid, in terms of content of particles having a particle size of 1 μm or more, is preferably 100 or less and more preferably 50 or less per 1 mL of the treatment liquid. A lower limit thereof is preferably 0 or more, and more preferably 0.01 or more per milliliter of the treatment liquid.

The coarse particles contained in the treatment liquid correspond to, for example, particles such as rubbish, dust, organic solid, and inorganic solid, which are contained as impurities in raw materials, and particles such as rubbish, dust, organic solid, and inorganic solid, which are brought in as contaminants during the preparation of the treatment liquid, in which those particles are finally present as particles without being dissolved in the treatment liquid.

The number of coarse particles present in the treatment liquid can be measured in a liquid phase using a commercially available particle counter.

Examples of a method for removing the coarse particles include a purification treatment such as filtering, which will be described later.

### <Production Method of Treatment Liquid>

The treatment liquid can be produced by a known method. Hereinafter, a production method of the treatment liquid will be described in detail.

### [Liquid Preparation Step]

As a method of preparing the treatment liquid, for example, the treatment liquid can produced by mixing each of the above-described components.

The order and/or timing of mixing the above-described components is not particularly limited, and for example, the polycarboxylic acid, the specific polymer, and other components (the amino alcohol, the antibacterial agent, and the like) may be sequentially charged into a container containing a purified solvent (for example, pure water), and then the mixture may be stirred and mixed. In addition, after the mixing, a pH adjuster may be added thereto to adjust the pH of the mixed solution.

In a case where the solvent and the components are charged into the container, the solvent and the components may be charged at once, or may be charged in a divided manner a plurality of times.

As a stirring device and a stirring method used for preparing the treatment liquid, a known device may be used as a stirrer or a disperser. Examples of the stirrer include an industrial mixer, a portable stirrer, a mechanical stirrer, and a magnetic stirrer. Examples of the disperser include an industrial disperser, a homogenizer, an ultrasonic disperser, and a beads mill.

The mixing of the components in the step of preparing the treatment liquid, a refining treatment described later, and storage of the produced treatment liquid are preferably performed at 40° C. or lower, and more preferably performed at 30° C. or lower. In addition, the lower limit thereof is preferably 5° C. or higher, and more preferably 10° C. or higher. By performing the preparation of the treatment liquid, the treatment, and/or the storage of the treatment liquid in the above-described temperature ranges, the performance can be stably maintained for a long period of time.

### (Purification Treatment)

It is preferable to subject any one or more of the raw materials for preparing the treatment liquid to a purification treatment in advance. Examples of the purification treatment include known methods such as distillation, ion exchange, and filtration (filtering).

Regarding a degree of purification, it is preferable to carry out the purification treatment until the purity of the raw material is 99% by mass or more, and it is more preferable to carry out the purification treatment until the purity of the stock solution is 99.9% by mass or more.

### (Container)

The treatment liquid (including an aspect of a diluted treatment liquid described later) can be added in any container to be stored and transported as long as problems such as corrosiveness do not arise.

In application for a semiconductor, the container is preferably a container which has a high degree of cleanliness inside the container and in which the elution of impurities from an interior wall of an accommodating portion of the container into the each liquid is suppressed. Examples of such a container include various containers commercially available as a container for a semiconductor treatment liquid, such as “CLEAN BOTTLE” series manufactured by AICELLO MILIM CHEMICAL Co., Ltd. and “PURE BOTTLE” manufactured by Kodama Plastics Co., Ltd., but the container is not limited thereto.

In addition, the container accommodating the treatment liquid is preferably a container in which a liquid contact portion with each liquid, such as the interior wall of the accommodating portion of the container, is made of a fluororesin (perfluororesin) or metal subjected to an antirust treatment and a metal elution prevention treatment.

The interior wall of the container is preferably formed from one or more resins selected from the group consisting of a polyethylene resin, a polypropylene resin, and a polyethylene-polypropylene resin; another resin different from these resins; or a metal which has been subjected to an antirust treatment and a metal elution prevention treatment, such as stainless steel, Hastelloy, Inconel, and Monel.

The inside of these containers is preferably cleaned before filling the treatment liquid. With regard to a liquid used for the cleaning, the amount of metal impurities in the liquid is preferably reduced. The treatment liquid may be bottled in a container such as a gallon bottle and a coated bottle after the production, and then may be transported and stored.

In order to prevent changes in the components of the treatment liquid during the storage, the inside of the container may be purged with an inert gas (such as nitrogen and argon) having a purity of 99.99995% by volume or more. In particular, a gas with a low moisture content is preferable. In addition, during the transportation and the storage, the temperature may be normal temperature or may be controlled in a range of −20° C. to 20° C. to prevent deterioration.

### (Clean Room)

It is preferable that handlings including production of the treatment liquid, opening and cleaning of the container, and filling of the treatment liquid, treatment analysis, and measurements are all performed in a clean room. It is preferable that the clean room meets the 14644-1 clean room standard. The clean room preferably satisfies any of International Organization for Standardization (ISO) class 1, ISO class 2, ISO class 3, or ISO class 4, more preferably ISO class 1 or ISO class 2, and still more preferably ISO class 1.

### [Dilution Step]

The above-described treatment liquid may be used as a treatment liquid (diluted treatment liquid) which is diluted after undergoing a dilution step of diluting the treatment liquid using a diluent. That is, a concentrated solution may be prepared, and then diluted and used as the treatment liquid.

The diluted treatment liquid is also an aspect of the treatment liquid according to the embodiment of the present invention as long as it satisfies the requirements of the present invention.

Examples of the diluted liquid include water and an aqueous solution including ammonia.

It is preferable to subject the diluted liquid which is used in the dilution step to a purification treatment in advance. In addition, it is more preferable that the diluted treatment liquid obtained in the dilution step is subjected to a purification treatment.

Examples of the purification treatment include an ion component reducing treatment using an ion exchange resin, an RO membrane, or the like, and a foreign matter removal using filtering described as the purification treatment for the treatment liquid above, and it is preferable to carry out any of these treatments.

A dilution rate of the treatment liquid in the dilution step may be appropriately adjusted according to the type and content of each component, and the use target and purpose of the treatment liquid. A ratio (dilution ratio) of the diluted treatment liquid to the treatment liquid before the dilution is preferably 1.5 to 10,000 times, more preferably 2 to 2,000 times, and still more preferably 50 to 1,000 times in terms of volume ratio (volume ratio at 23° C.).

A change in pH before and after the dilution (a difference between the pH of the treatment liquid before the dilution and the pH of the diluted treatment liquid) is preferably 2.0 or less, more preferably 1.8 or less, and still more preferably 1.5 or less.

It is preferable that the pH of the treatment liquid before the dilution and the pH of the diluted treatment liquid are each in the above-described suitable aspect.

A specific method for the dilution step of diluting the treatment liquid may be performed according to the step of preparing the treatment liquid described above. A stirring device and a stirring method used in the dilution step may also be performed using the known stirring device described in the step of preparing the treatment liquid above.

### <Use of Treatment Liquid>

The treatment liquid is used for various treatments for manufacturing a semiconductor. Among these, the treatment liquid is preferably used in a cleaning step of cleaning an object to be treated (preferably, a semiconductor substrate) which has been subjected to a chemical mechanical polishing (CMP) treatment.

As described above, the diluted treatment liquid obtained by diluting the treatment liquid may be used for cleaning the object to be treated.

### [Object to be Treated]

The object to be treated preferably contains at least one (specific material) selected from the group consisting of polysilicon, silicon carbide, and silicon carbonitride.

The above-described silicon carbonitride is a compound containing silicon (Si), carbon (C), and nitrogen (N), and a content ratio of silicon (Si), carbon (C), and nitrogen (N) is not particularly limited.

Examples of the object to be treated include a substrate having a layer containing polysilicon (polysilicon layer), a layer containing silicon carbide (silicon carbide layer), and a layer containing silicon carbonitride (silicon carbonitride layer).

In a case where the substrate has the above-described specific material, a location where a layer containing the specific material is present may be, for example, any of front and back surfaces, side surfaces, inside of a groove, or the like of the substrate. In addition, in a case where the substrate has the layer containing the specific material, the layer containing the specific material is not only directly present on the surface of the substrate, but also present on the substrate through another layer.

The layer containing the specific material may be disposed only on one main surface of the substrate, or may be disposed on both main surfaces of the substrate. The layer containing the specific material may be disposed on the entire main surface of the substrate, or may be disposed on a part of the main surface of the substrate.

The present treatment liquid exhibits good affinity even to a material which exhibits a high contact angle with respect to water (for example, polysilicon, silicon carbide, and silicon carbonitride).

The object to be treated may include an insulating film other than the layer containing the specific material.

The other insulating film is not particularly limited, and examples thereof include an insulating film containing one or more materials selected from the group consisting of silicon nitride (SiN), silicon oxide, silicon oxycarbide (SiOC), silicon oxynitride, and tetraethoxysilane (TEOS). Among these, SiN or TEOS is preferable as the above-described material. In addition, the insulating film may be composed of a plurality of films.

The object to be treated may have various layers and/or structures as desired, in addition to the above description. For example, in a case where the object to be treated is a substrate, the object to be treated may have a member such as a barrier layer (for example, a layer containing titanium, titanium nitride, tantalum, tantalum nitride, or the like), a metal wire, an oxide film, a gate electrode, a source electrode, a drain electrode, an insulating layer, a ferromagnetic layer, an integrated circuit structure, and/or a non-magnetic layer.

### <CMP Treatment>

The CMP treatment is a treatment in which a surface of a substrate having the electrode film, the metal wire film, the barrier metal, and the insulating film is flattened by a combined action of a chemical action and a mechanical polishing using a polishing slurry including polishing fine particles (abrasive grains).

On a surface of the object to be treated, which has been subjected to the CMP treatment, abrasive grains (for example, silica, alumina, and the like) used in the CMP treatment, and non-metallic impurities and metal impurities derived from a polysilicon film, a silicon carbide film, a silicon carbonitride film, a metal wire film, another insulating film, and a barrier metal may remain. In addition, an organic residue derived from a CMP treatment liquid used in the CMP treatment may remain.

In particular, in a case of performing the CMP treatment on the object to be treated, containing polysilicon, silicon carbide, or silicon carbonitride, a film containing polysilicon, silicon carbide, or silicon carbonitride is often protected with a surfactant or the like because the film is easily polished, and the surfactant or the like is likely to remain on polysilicon, silicon carbide, or silicon carbonitride as an organic residue.

For example, since these impurities may cause a short-circuit between wiring lines and deteriorate electrical characteristics of the object to be treated, the object to be treated, which has been subjected to the CMP treatment, is subjected to a cleaning treatment for removing these impurities from the surface.

Examples of the object to be treated, which has been subjected to the CMP treatment, include substrates which have been subjected to the CMP treatment, described in Journal of the Japan Society for Precision Engineering, Vol. 84, No. 3, 2018, but the present invention is not limited thereto.

### <Buffing Treatment>

The object to be treated may be subjected to the CMP treatment and then a buffing treatment.

The buffing treatment is a treatment of reducing impurities on the surface of the object to be treated using a polishing pad. Specifically, the surface of the object to be treated, which has been subjected to the CMP treatment, is brought into contact with the polishing pad, and the object to be treated and the polishing pad are relatively slid while supplying a composition for buffing to a contact portion. As a result, impurities on the surface of the object to be treated are removed by a frictional force of the polishing pad and a chemical action of a composition for the buffing treatment.

As the composition for the buffing treatment, a known composition for the buffing treatment can be appropriately used depending on the type of the object to be treated, and the type and amount of the impurities to be removed. Examples of components contained in the composition for buffing include a water-soluble polymer such as polyvinyl alcohol, water as a dispersion medium, and an acid such as nitric acid.

In addition, in one embodiment of the buffing treatment, it is preferable that the object to be treated is buffed using the above-described treatment liquid as the composition for the buffing treatment.

A polishing device, polishing conditions, and the like, which are used in the buffing treatment, can be appropriately selected from known devices and conditions according to the type of the object to be treated, the object to be removed, and the like. Examples of the buffing treatment include treatments described in paragraphs to of WO2017/169539A, the contents of which are incorporated herein by reference.

### [Cleaning Method of Object to be Treated]

As described above, it is preferable that the treatment liquid is used for cleaning the object to be treated.

The cleaning method of the object to be treated preferably includes a cleaning step of cleaning the object to be treated, which has been subjected to the CMP treatment, using the present treatment liquid.

The above-described cleaning step may be a known method performed on the object to be treated. For example, a method commonly used in this field, such as scrub cleaning in which a cleaning member such as a brush is physically brought into contact with a surface of the object to be treated while supplying the treatment liquid to the object to be treated, thereby removing residues; an immersion method in which the object to be treated is immersed in the treatment liquid; a spinning (dropping) method in which the treatment liquid is dropped while rotating the object to be treated; and a spray method in which the treatment liquid is sprayed may be adopted as appropriate.

In the cleaning by the immersion method, from the viewpoint that impurities remaining on the surface of the object to be treated can be further reduced, it is preferable that the object to be treated immersed in the treatment liquid is subjected to an ultrasonic treatment.

The above-described cleaning step may be carried out only once or twice or more. In a case of carrying out the cleaning two or more times, the same method may be repeated or different methods may be combined.

The cleaning method of the object to be treated may be a single-wafer method or a batch method.

The single-wafer method is generally a method of treating the objects to be treated one by one, and the batch method is generally a method of treating a plurality of the objects to be treated at the same time.

A temperature of the treatment liquid used for cleaning the object to be treated is not particularly limited as long as it is a temperature usually used in this field. Generally, the cleaning is carried out at room temperature (approximately 25° C.), but any temperature can be selected in order to improve the cleanability and suppress the damage resistance to a member. For example, the temperature of the treatment liquid is preferably 10° C. to 60° C., and more preferably 15° C. to 50° C.

A pH of the treatment liquid is preferably the suitable aspect of the pH of the treatment liquid described above. A pH of the diluted treatment liquid is also preferably the suitable aspect of the pH of the treatment liquid described above.

A cleaning time in the cleaning of the object to be treated can be appropriately changed depending on the type, content, and the like of the components contained in the treatment liquid. Practically, it is preferably 10 seconds to 2 minutes, more preferably 20 seconds to 1 minute and 30 seconds, and still more preferably 30 seconds to 1 minute.

A supply amount (supply rate) of the treatment liquid in the cleaning step of the object to be treated is preferably 50 to 5,000 mL/min and more preferably 500 to 2,000 mL/min.

In the cleaning of the object to be treated, a mechanical stirring method may be used in order to further improve the cleaning ability of the treatment liquid.

Examples of the mechanical stirring method include a method in which the treatment liquid is circulated on the object to be treated, a method in which the treatment liquid is flown or sprayed on the object to be treated, and a method in which the treatment liquid is stirred with ultrasonic waves or megasonic waves.

After the cleaning of the object to be treated, a step of rinsing and cleaning the object to be treated with a solvent (hereinafter, also referred to as “rinsing step”) may be performed.

The rinsing step is preferably a step which is carried out continuously subsequently after the cleaning step of the object to be treated, in which the rinsing is carried out with a rinsing solvent (rinsing liquid) over 5 seconds to 5 minutes. The rinsing step may be performed using the above-described mechanical stirring method.

Examples of the rinsing solvent include water (preferably deionized (DI) water), methanol, ethanol, isopropyl alcohol, N-methylpyrrolidinone, γ-butyrolactone, dimethyl sulfoxide, ethyl lactate, and propylene glycol monomethyl ether acetate. In addition, an aqueous rinsing liquid having a pH of more than 8.0 (aqueous ammonium hydroxide which has been diluted, or the like) may be used.

As a method in which the rinsing solvent is brought into contact with the object to be treated, the above-described method in which the treatment liquid is brought into contact with the object to be treated can be similarly applied.

In addition, a drying step of drying the object to be treated may be performed after the above-described rinsing step.

Examples of the drying method include a spin drying method, a method of flowing a dry gas onto the object to be treated, a method of heating a substrate by a heating unit such as a hot plate and an infrared lamp, a Marangoni drying method, a Rotagoni drying method, an isopropyl alcohol (IPA) drying method, and a method of combining any of these methods.

### EXAMPLES

Hereinbelow, the present invention will be described in more detail with reference to Examples. The materials, the amounts of the materials to be used, the proportions, and the like shown in the Examples below may be modified as appropriate as long as the modifications do not depart from the spirit of the present invention. That is, the scope of the present invention is construed as being limited to Examples shown below.

In the following examples, a pH of a concentrated solution described later was measured at 25° C. in accordance with JIS Z 8802-1984 using a pH meter (manufactured by Horiba, Ltd., model “F-74”).

In addition, in production of treatment liquids of Examples and Comparative Examples, all of handling of a container, and production, filling, storage, and analytical measurement of the treatment liquids were performed in a clean room satisfying a level of ISO Class 2 or lower.

### [Raw Materials of Treatment Liquid]

The following compounds were used to produce a treatment liquid.

As various components used in Examples, those all classified into a semiconductor grade or a high-purity grade equivalent thereto were used.

### [Polycarboxylic Acid]

Citric acid
Oxalic acid
Malonic acid
Succinic acid
Malic acid
Tartaric acid: L-tartaric acid

### [Specific Polymer]

In the following specific polymers, in a case where a weight-average molecular weight is not described, Mw=6000. In addition, in any of the specific polymers, a ratio a/b (copolymerization ratio) of the number of moles a of the repeating unit A to the number of moles b of the repeating unit B was 50/50.
Polymer-1a: acrylic acid-methyl acrylate copolymer (Mw=800)
Polymer-1b: acrylic acid-methyl acrylate copolymer (Mw=6000)
Polymer-1c: acrylic acid-methyl acrylate copolymer (Mw=30000)
Polymer-1d: acrylic acid-methyl acrylate copolymer (Mw=50000)
Polymer-1e: acrylic acid-methyl acrylate copolymer (Mw=75000)
Polymer-2: acrylic acid-butyl acrylate copolymer
Polymer-3: acrylic acid-N,N-dimethylacrylamide copolymer
Polymer-4: acrylic acid-(2-ethylhexyl) acrylate copolymer
Polymer-5: acrylic acid-acrylamide copolymer
Polymer-6: maleic acid-ethyl acrylate copolymer
Polymer-7: maleic acid-N,N-dimethylacrylamide copolymer
Polymer-8: maleic acid-butyl acrylate copolymer
Polymer-9: maleic acid-methyl acrylate copolymer
Polymer-10: maleic acid-diacetone acrylamide copolymer
Polymer-11: styrene sulfonic acid-butyl acrylate copolymer
Polymer-12: styrene sulfonic acid-N,N-dimethylacrylamide copolymer
Polymer-13: vinylphosphonic acid-butyl acrylate copolymer
Polymer-14: vinylphosphonic acid-N,N-dimethylacrylamide copolymer
Polymer-15: styrene-maleic acid copolymer

In the above-described specific polymers, a C log P of the nonionic monomer for the repeating unit A derived from a nonionic monomer is shown below.
Methyl acrylate: 0.79
Ethyl acrylate: 1.33
Butyl acrylate: 2.39
2-Ethylhexyl acrylate: 4.33
N,N-dimethylacrylamide: −0.59
Acrylamide: −0.79

### [Resin (Resin not Corresponding to Specific Polymer)]

Polyacrylic acid
Polyacrylamide

### [Amino Alcohol]

Tris: tris (hydroxymethyl) aminomethane
MEA: monoethanolamine
DEA: diethanolamine
MDEA: N-methyldiethanolamine
Bis-Tris: bis(2-hydroxyethyl)aminotrist(hydroxymethyl)methane
Bis-TrisP: 1,3-bis[tris(hydroxymethyl)methylamino]propane

### [Antibacterial Agent]

MIT: 2-methyl-4-isothiazolin-3-one
Sorbic acid
MIT/OIT: mixture of MIT and 2-octyl-4-isothiazolin-3-one (OIT) (mass ratio: 1:5)
Cresol
Dehydroacetic acid
Benzoic acid
Catechol
PHMB: polyhexamethylene biguanide
CHG: chlorhexidine gluconate

### [PH Adjuster and Water]

In a step of producing the treatment liquid in the present example, potassium hydroxide (KOH) or nitric acid (HNO₃) as a pH adjuster and ultrapure water were used.

A content of the pH adjuster was 2% by mass or less with respect to the total mass of the concentrated solution in a case of producing any of the treatment liquids of Examples and Comparative Examples.

### [Production of Treatment Liquid]

A method for producing a treatment liquid of Example 1 will be described.

The citric acid, Polymer-1b, Tris, and MIT were added to ultrapure water according to the table described later, and then a pH adjusting agent was added thereto so that a pH of the prepared concentrated solution was 1.5. The obtained mixed solution was sufficiently stirred to obtain a concentrated solution.

The remainder (components other than the citric acid, Polymer-1b, Tris, MIT, and the pH adjuster) in the concentrated solution is ultrapure water.

The obtained concentrated solution was diluted with ultrapure water at the dilution ratio described in the table to obtain a treatment liquid of Example 1.

Treatment liquids of each of Examples and Comparative Examples were produced by the same production method as in Example 1, except that the types and contents of the respective components were adjusted according to the tables described later. In each of Examples and Comparative Examples, the concentrated solution was prepared in the same manner as in Example 1, and diluted at a predetermined dilution ratio to prepare a predetermined treatment liquid.

### [Evaluation]

### [Defect Removability]

Defect removability in a case where the object after the CMP treatment was cleaned was evaluated using the treatment liquid of each of Examples or Comparative Examples prepared as described above.

### —CMP Treatment—

The object was subjected to a CMP treatment while supplying a slurry (polishing liquid) using, as a polishing device, a device “FREX-300X” manufactured by Ebara Corporation. The object subjected to the CMP treatment, the formulation of the polishing liquid, and the polishing conditions are as follows.

### (Object)

12-inch wafer in which polysilicon (poly-Si) is formed on an Si substrate
12-inch wafer in which silicon carbide (SiC) is formed on an Si substrate
12-inch wafer in which silicon carbonitride (SiCN) is formed on an Si substrate
12-inch wafer in which silicon nitride (SiN) is formed on an Si substrate

### (Formulation of Polishing Liquid)

| | |
|---|---|
| Colloidal silica (PL3, manufactured by FUSO | 3% by mass |
| CHEMICAL CO., LTD.) | |
| Citric acid | 0.20% by mass |
| Dodecylbenzenesulfonic acid (DBS) | 0.05% by mass |
| Water and KOH/HNO₃ (nitrate) | remainder |

The pH of the above-described polishing liquid was adjusted to 10.0 using the KOH/HNO₃.

### (Polishing Conditions)

| Table rotation speed | 80 | rpm |
|---|---|---|
| Head rotation speed | 78 | rpm |
| Polishing pressure | 140 | hPa |
| Polishing time | 60 | seconds |
| Polishing pad (manufactured by Rodel-Nitta) | VP6000 | |
| Polishing liquid supply rate | 250 | ml/min |

### —Defect Evaluation—

Defect removability in a case where each of the objects (wafer with poly-Si, wafer with SiC, wafer with SiCN, or wafer with SiN) after the CMP treatment was subjected to a cleaning treatment using the treatment liquid was evaluated.

Using each treatment liquid, the object after the CMP treatment was cleaned for 30 seconds by a cleaning unit 1 (sheet cleaning by brush scrubbing), and then further cleaned for 30 seconds by a cleaning unit 2 (sheet cleaning by brush scrubbing).

After the cleaning treatment, a rinsing treatment was performed for 60 seconds using ultrapure water, and finally, a spin drying was performed at a rotation speed of 1,000 rpm while blowing N2 onto the wafer surface in a drying unit, thereby performing a dry-out treatment of the wafer.

Using a defect detection device (ComPlus II), the number of defects having a length of 0.1 μm or more was detected on the polished surface of the obtained wafer, and each defect was observed with a scanning electron microscope (SEM) to perform defect classification. As necessary, the constitutional elements were analyzed by energy dispersion type X-ray analysis apparatus (EDX) to specify the components. As a result, the number of defects based on residues was obtained, and cleaning performance was evaluated according to the following evaluation standard (evaluation A was the best in cleaning performance).

### (Evaluation Standard)

A: number of defects per wafer was less than 100.
B: number of defects per wafer was 100 or more and less than 300.
C: number of defects per wafer was 300 or more and less than 500.
D: number of defects per wafer was 500 or more and less than 1,000.
E: number of defects per wafer was 1,000 or more.

### [Result]

The following tables show the formulation, the dilution ratio, and the evaluation result of the concentrated solution of the treatment liquid of each of Examples and Comparative Examples. Contents in the tables are indicated as a concentration (unit: % by mass) with respect to the total mass of the concentrated solution of the treatment liquid.

In the tables, the column of “Mw” indicates a weight-average molecular weight.

The column of “A)/B)” indicates a mass ratio of the content of the polycarboxylic acid to the content of the specific polymer.

The column of “B)/C)” indicates a mass ratio of the specific polymer to the content of the amino alcohol.

The column of “(B)/D)” indicates a mass ratio of the content of the specific polymer to the content of the antibacterial agent.

The numerical value in the column of “pH” indicates the pH of the concentrated solution at 25° C. measured by the above-described pH meter.

The column of “Dilution ratio (times)” indicates a dilution ratio (volume ratio) in a case where the concentrated solution having the formulation described in the tables is used in the test. For example, in Example 1, it means that each evaluation was carried out using a treatment liquid obtained by diluting the concentrated solution having the formulation shown in Table 1 with ultrapure water at a volume ratio of 200 times.

TABLE 1

| | A) Polycarboxylic | | B) Specific | | | C) Amino | | D) Antibacterial | | | | | | | | | | |
|---|---|---|---|---|---|---|---|---|---|---|---|---|---|---|---|---|---|---|
| | acid | | polymer | | | alcohol | | agent | | | | | | Dilution | poly-Si | SiC | SiCN | SiN |
| | | Content | | | Content | | Content | | Content | | | | | ratio | defect | defect | defect | defect |
| | Type | (% by mass) | Type | Mw | (% by mass) | Type | (% by mass) | Type | (% by mass) | A)/B) | B)/C) | B)/D) | pH | (times) | removability | removability | removability | removability |
| Example 1 | Citric | 1.5 | Polymer-1b | 6000 | 0.5 | Tris | 4.5 | MIT | 0.05 | 3.0 | 0.111 | 10.0 | 1.5 | 200 | C | C | C | C |
| | acid | | | | | | | | | | | | | | | | | |
| Example 2 | Citric | 1.5 | Polymer-1b | 6000 | 0.5 | Tris | 4.5 | MIT | 0.05 | 3.0 | 0.111 | 10.0 | 2 | 200 | B | B | B | B |
| | acid | | | | | | | | | | | | | | | | | |
| Example 3 | Citric | 1.5 | Polymer-1b | 6000 | 0.5 | Tris | 4.5 | MIT | 0.05 | 3.0 | 0.111 | 10.0 | 3 | 200 | B | B | B | A |
| | acid | | | | | | | | | | | | | | | | | |
| Example 4 | Citric | 1.5 | Polymer-1b | 6000 | 0.5 | Tris | 4.5 | MIT | 0.05 | 3.0 | 0.111 | 10.0 | 4 | 200 | B | B | B | A |
| | acid | | | | | | | | | | | | | | | | | |
| Example 5 | Citric | 1.5 | Polymer-1b | 6000 | 0.5 | Tris | 4.5 | MIT | 0.05 | 3.0 | 0.111 | 10.0 | 5 | 200 | B | B | B | A |
| | acid | | | | | | | | | | | | | | | | | |
| Example 6 | Citric | 1.5 | Polymer-1b | 6000 | 0.5 | Tris | 4.5 | MIT | 0.05 | 3.0 | 0.111 | 10.0 | 6 | 200 | B | B | B | A |
| | acid | | | | | | | | | | | | | | | | | |
| Example 7 | Citric | 1.5 | Polymer-1b | 6000 | 0.5 | Tris | 4.5 | MIT | 0.05 | 3.0 | 0.111 | 10.0 | 7 | 200 | B | B | B | A |
| | acid | | | | | | | | | | | | | | | | | |
| Example 8 | Citric | 1.5 | Polymer-1b | 6000 | 0.5 | Tris | 4.5 | MIT | 0.05 | 3.0 | 0.111 | 10.0 | 8 | 200 | B | B | B | A |
| | acid | | | | | | | | | | | | | | | | | |
| Example 9 | Citric | 1.5 | Polymer-1b | 6000 | 0.5 | Tris | 4.5 | MIT | 0.05 | 3.0 | 0.111 | 10.0 | 4 | 10 | A | A | A | A |
| | acid | | | | | | | | | | | | | | | | | |
| Example 10 | Citric | 1.5 | Polymer-1b | 6000 | 0.5 | Tris | 4.5 | MIT | 0.05 | 3.0 | 0.111 | 10.0 | 5 | 10 | A | A | A | A |
| | acid | | | | | | | | | | | | | | | | | |
| Example 11 | Citric | 1.5 | Polymer-1b | 6000 | 0.5 | Tris | 4.5 | MIT | 0.05 | 3.0 | 0.111 | 10.0 | 6 | 10 | A | A | A | A |
| | acid | | | | | | | | | | | | | | | | | |
| Example 12 | Citric | 1.5 | Polymer-1b | 6000 | 0.5 | Tris | 4.5 | MIT | 0.05 | 3.0 | 0.111 | 10.0 | 7 | 10 | A | A | A | A |
| | acid | | | | | | | | | | | | | | | | | |
| Example 13 | Citric | 1.5 | Polymer-1b | 6000 | 0.5 | Tris | 4.5 | MIT | 0.05 | 3.0 | 0.111 | 10.0 | 8 | 10 | A | A | A | A |
| | acid | | | | | | | | | | | | | | | | | |
| Example 14 | Citric | 1.5 | Polymer-1b | 6000 | 0.5 | Tris | 4.5 | MIT | 0.05 | 3.0 | 0.111 | 10.0 | 4 | 50 | A | A | A | A |
| | acid | | | | | | | | | | | | | | | | | |
| Example 15 | Citric | 1.5 | Polymer-1b | 6000 | 0.5 | Tris | 4.5 | MIT | 0.05 | 3.0 | 0.111 | 10.0 | 5 | 50 | A | A | A | A |
| | acid | | | | | | | | | | | | | | | | | |
| Example 16 | Citric | 1.5 | Polymer-1b | 6000 | 0.5 | Tris | 4.5 | MIT | 0.05 | 3.0 | 0.111 | 10.0 | 6 | 50 | A | A | A | A |
| | acid | | | | | | | | | | | | | | | | | |
| Example 17 | Citric | 1.5 | Polymer-1b | 6000 | 0.5 | Tris | 4.5 | MIT | 0.05 | 3.0 | 0.111 | 10.0 | 7 | 50 | A | A | A | A |
| | acid | | | | | | | | | | | | | | | | | |
| Example 18 | Citric | 1.5 | Polymer-1b | 6000 | 0.5 | Tris | 4.5 | MIT | 0.05 | 3.0 | 0.111 | 10.0 | 8 | 50 | A | A | A | A |
| | acid | | | | | | | | | | | | | | | | | |
| Example 19 | Citric | 1.5 | Polymer-1b | 6000 | 0.5 | Tris | 4.5 | MIT | 0.05 | 3.0 | 0.111 | 10.0 | 4 | 400 | C | C | C | B |
| | acid | | | | | | | | | | | | | | | | | |
| Example 20 | Citric | 1.5 | Polymer-1b | 6000 | 0.5 | Tris | 4.5 | MIT | 0.05 | 3.0 | 0.111 | 10.0 | 5 | 400 | C | C | C | B |
| | acid | | | | | | | | | | | | | | | | | |
| Example 21 | Citric | 1.5 | Polymer-1b | 6000 | 0.5 | Tris | 4.5 | MIT | 0.05 | 3.0 | 0.111 | 10.0 | 6 | 400 | C | C | C | B |
| | acid | | | | | | | | | | | | | | | | | |
| Example 22 | Citric | 1.5 | Polymer-1b | 6000 | 0.5 | Tris | 4.5 | MIT | 0.05 | 3.0 | 0.111 | 10.0 | 7 | 400 | C | C | C | B |
| | acid | | | | | | | | | | | | | | | | | |
| Example 23 | Citric | 1.5 | Polymer-1b | 6000 | 0.5 | Tris | 4.5 | MIT | 0.05 | 3.0 | 0.111 | 10.0 | 8 | 400 | C | C | C | B |
| | acid | | | | | | | | | | | | | | | | | |
| Example 24 | Citric | 1.5 | Polymer-1b | 6000 | 0.5 | Tris | 4.5 | MIT | 0.05 | 3.0 | 0.111 | 10.0 | 9 | 200 | B | B | B | B |
| | acid | | | | | | | | | | | | | | | | | |
| Example 25 | Citric | 1.5 | Polymer-1b | 6000 | 0.5 | Tris | 4.5 | MIT | 0.05 | 3.0 | 0.111 | 10.0 | 10 | 200 | B | B | B | B |
| | acid | | | | | | | | | | | | | | | | | |
| Example 26 | Citric | 1.5 | Polymer-1b | 6000 | 0.5 | Tris | 4.5 | MIT | 0.05 | 3.0 | 0.111 | 10.0 | 11 | 200 | C | C | C | C |
| | acid | | | | | | | | | | | | | | | | | |
| Example 27 | Citric | 1.5 | Polymer-1b | 6000 | 0.5 | Tris | 4.5 | MIT | 0.05 | 3.0 | 0.111 | 10.0 | 12 | 200 | C | C | C | C |
| | acid | | | | | | | | | | | | | | | | | |
| Example 28 | Citric | 1.5 | Polymer-1a | 800 | 0.5 | Tris | 4.5 | MIT | 0.05 | 3.0 | 0.111 | 10.0 | 6 | 200 | C | C | C | C |
| | acid | | | | | | | | | | | | | | | | | |
| Example 29 | Citric | 1.5 | Polymer-1b | 6000 | 0.5 | — | — | MIT | 0.05 | 3.0 | — | 10.0 | 6 | 200 | B | B | B | B |
| | acid | | | | | | | | | | | | | | | | | |
| Example 30 | Citric | 1.5 | Polymer-1b | 6000 | 0.5 | Tris | 4.5 | — | — | 3.0 | 0.111 | — | 6 | 200 | B | B | B | C |
| | acid | | | | | | | | | | | | | | | | | |

TABLE 2

| | A) Polycarboxylic | | B) Specific | | | C) Amino | | D) Antibacterial | | | | | | | | | | |
|---|---|---|---|---|---|---|---|---|---|---|---|---|---|---|---|---|---|---|
| | acid | | polymer | | | alcohol | | agent | | | | | | Dilution | removability | SiC | SiCN | SiN |
| | | Content | | | Content | | Content | | Content | | | | | ratio | poly-Si | defect | defect | defect |
| | Type | (% by mass) | Type | Mw | (% by mass) | Type | (% by mass) | Type | (% by mass) | A)/B) | B)/C) | B)/D) | pH | (times) | defect | removability | removability | removability |
| Example 31 | Citric | 1.5 | Polymer-1c | 30000 | 0.5 | Tris | 4.5 | MIT | 0.05 | 3.0 | 0.111 | 10.0 | 6 | 200 | B | B | B | C |
| | acid | | | | | | | | | | | | | | | | | |
| Example 32 | Citric | 1.5 | Polymer-1d | 50000 | 0.5 | Tris | 4.5 | MIT | 0.05 | 3.0 | 0.111 | 10.0 | 6 | 200 | B | B | B | C |
| | acid | | | | | | | | | | | | | | | | | |
| Example 33 | Citric | 1.5 | Polymer-le | 75000 | 0.5 | Tris | 4.5 | MIT | 0.05 | 3.0 | 0.111 | 10.0 | 6 | 200 | C | C | C | C |
| | acid | | | | | | | | | | | | | | | | | |
| Example 34 | Citric | 1.5 | Polymer-2 | 6000 | 0.5 | Tris | 4.5 | MIT | 0.05 | 3.0 | 0.111 | 10.0 | 6 | 200 | A | A | A | A |
| | acid | | | | | | | | | | | | | | | | | |
| Example 35 | Citric | 1.5 | Polymer-3 | 6000 | 0.5 | Tris | 4.5 | MIT | 0.05 | 3.0 | 0.111 | 10.0 | 6 | 200 | B | B | B | A |
| | acid | | | | | | | | | | | | | | | | | |
| Example 36 | Citric | 1.5 | Polymer-4 | 6000 | 0.5 | Tris | 4.5 | MIT | 0.05 | 3.0 | 0.111 | 10.0 | 6 | 200 | A | A | A | A |
| | acid | | | | | | | | | | | | | | | | | |
| Example 37 | Citric | 1.5 | Polymer-5 | 6000 | 0.5 | Tris | 4.5 | MIT | 0.05 | 3.0 | 0.111 | 10.0 | 6 | 200 | C | C | C | A |
| | acid | | | | | | | | | | | | | | | | | |
| Example 38 | Citric | 1.5 | Polymer-6 | 6000 | 0.5 | Tris | 4.5 | MIT | 0.05 | 3.0 | 0.111 | 10.0 | 6 | 200 | A | A | A | A |
| | acid | | | | | | | | | | | | | | | | | |
| Example 39 | Citric | 1.5 | Polymer-7 | 6000 | 0.5 | Tris | 4.5 | MIT | 0.05 | 3.0 | 0.111 | 10.0 | 6 | 200 | B | B | B | A |
| | acid | | | | | | | | | | | | | | | | | |
| Example 40 | Citric | 1.5 | Polymer-8 | 6000 | 0.5 | Tris | 4.5 | MIT | 0.05 | 3.0 | 0.111 | 10.0 | 6 | 200 | A | A | A | A |
| | acid | | | | | | | | | | | | | | | | | |
| Example 41 | Citric | 1.5 | Polymer-9 | 6000 | 0.5 | Tris | 4.5 | MIT | 0.05 | 3.0 | 0.111 | 10.0 | 6 | 200 | B | B | B | A |
| | acid | | | | | | | | | | | | | | | | | |
| Example 42 | Citric | 1.5 | Polymer-10 | 6000 | 0.5 | Tris | 4.5 | MIT | 0.05 | 3.0 | 0.111 | 10.0 | 6 | 200 | B | B | B | A |
| | acid | | | | | | | | | | | | | | | | | |
| Example 43 | Citric | 1.5 | Polymer-11 | 6000 | 0.5 | Tris | 4.5 | MIT | 0.05 | 3.0 | 0.111 | 10.0 | 6 | 200 | A | A | A | A |
| | acid | | | | | | | | | | | | | | | | | |
| Example 44 | Citric | 1.5 | Polymer-12 | 6000 | 0.5 | Tris | 4.5 | MIT | 0.05 | 3.0 | 0.111 | 10.0 | 6 | 200 | B | B | B | A |
| | acid | | | | | | | | | | | | | | | | | |
| Example 45 | Citric | 1.5 | Polymer-13 | 6000 | 0.5 | Tris | 4.5 | MIT | 0.05 | 3.0 | 0.111 | 10.0 | 6 | 200 | A | A | A | A |
| | acid | | | | | | | | | | | | | | | | | |
| Example 46 | Citric | 1.5 | Polymer-14 | 6000 | 0.5 | Tris | 4.5 | MIT | 0.05 | 3.0 | 0.111 | 10.0 | 6 | 200 | B | B | B | A |
| | acid | | | | | | | | | | | | | | | | | |
| Example 47 | Citric | 1.5 | Polymer-15 | 6000 | 0.5 | Tris | 4.5 | MIT | 0.05 | 3.0 | 0.111 | 10.0 | 6 | 200 | C | C | C | C |
| | acid | | | | | | | | | | | | | | | | | |
| Example 48 | Citric | 1.5 | Polymer-5 | 6000 | 0.5 | Tris | 4.5 | MIT | 0.05 | 3.0 | 0.111 | 10.0 | 6 | 10 | A | A | A | A |
| | acid | | | | | | | | | | | | | | | | | |
| Example 49 | Citric | 1.5 | Polymer-7 | 6000 | 0.5 | Tris | 4.5 | MIT | 0.05 | 3.0 | 0.111 | 10.0 | 6 | 10 | A | A | A | A |
| | acid | | | | | | | | | | | | | | | | | |
| Example 50 | Citric | 1.5 | Polymer-9 | 6000 | 0.5 | Tris | 4.5 | MIT | 0.05 | 3.0 | 0.111 | 10.0 | 6 | 10 | A | A | A | A |
| | acid | | | | | | | | | | | | | | | | | |
| Example 51 | Citric | 1.5 | Polymer-5 | 6000 | 0.5 | Tris | 4.5 | MIT | 0.05 | 3.0 | 0.111 | 10.0 | 6 | 50 | B | B | B | A |
| | acid | | | | | | | | | | | | | | | | | |
| Example 52 | Citric | 1.5 | Polymer-7 | 6000 | 0.5 | Tris | 4.5 | MIT | 0.05 | 3.0 | 0.111 | 10.0 | 6 | 50 | A | A | A | A |
| | acid | | | | | | | | | | | | | | | | | |
| Example 53 | Citric | 1.5 | Polymer-9 | 6000 | 0.5 | Tris | 4.5 | MIT | 0.05 | 3.0 | 0.111 | 10.0 | 6 | 50 | A | A | A | A |
| | acid | | | | | | | | | | | | | | | | | |
| Example 54 | Citric | 1.5 | Polymer-4 | 6000 | 0.5 | Tris | 4.5 | MIT | 0.05 | 3.0 | 0.111 | 10.0 | 6 | 400 | B | B | B | A |
| | acid | | | | | | | | | | | | | | | | | |
| Example 55 | Citric | 1.5 | Polymer-6 | 6000 | 0.5 | Tris | 4.5 | MIT | 0.05 | 3.0 | 0.111 | 10.0 | 6 | 400 | B | B | B | A |
| | acid | | | | | | | | | | | | | | | | | |
| Example 56 | Citric | 1.5 | Polymer-8 | 6000 | 0.5 | Tris | 4.5 | MIT | 0.05 | 3.0 | 0.111 | 10.0 | 6 | 400 | B | B | B | A |
| | acid | | | | | | | | | | | | | | | | | |
| Example 57 | Citric | 1.5 | Polymer-11 | 6000 | 0.5 | Tris | 4.5 | MIT | 0.05 | 3.0 | 0.111 | 10.0 | 6 | 400 | B | B | B | A |
| | acid | | | | | | | | | | | | | | | | | |
| Example 58 | Citric | 1.5 | Polymer-2 | 6000 | 0.5 | — | — | MIT | 0.05 | 3.0 | — | 10.0 | 6 | 200 | B | B | B | A |
| | acid | | | | | | | | | | | | | | | | | |
| Example 59 | Citric | 1.5 | Polymer-6 | 6000 | 0.5 | — | — | MIT | 0.05 | 3.0 | — | 10.0 | 6 | 200 | C | C | C | A |
| | acid | | | | | | | | | | | | | | | | | |
| Example 60 | Citric | 1.5 | Polymer-11 | 6000 | 0.5 | — | — | MIT | 0.05 | 3.0 | — | 10.0 | 6 | 200 | B | B | B | A |
| | acid | | | | | | | | | | | | | | | | | |

TABLE 3

| | A) Polycarboxylic | | B) Specific | | | C) Amino | | D) Antibacterial | | | | | | | | | | |
|---|---|---|---|---|---|---|---|---|---|---|---|---|---|---|---|---|---|---|
| | acid | | polymer | | | alcohol | | agent | | | | | | Dilution | removability | SiC | SiCN | SiN |
| | | Content | | | Content | | Content | | Content | | | | | ratio | poly-Si | defect | defect | defect |
| | Type | (% by mass) | Type | Mw | (% by mass) | Type | (% by mass) | Type | (% by mass) | A)/B) | B)/C) | B)/D) | pH | (times) | defect | removability | removability | removability |
| Example 61 | Citric | 1.5 | Polymer-13 | 6000 | 0.5 | — | — | MIT | 0.05 | 3.0 | — | 10.0 | 6 | 200 | B | B | B | A |
| | acid | | | | | | | | | | | | | | | | | |
| Example 62 | Citric | 1.5 | Polymer-14 | 6000 | 0.5 | — | — | MIT | 0.05 | 3.0 | — | 10.0 | 6 | 200 | C | C | C | A |
| | acid | | | | | | | | | | | | | | | | | |
| Example 63 | Citric | 1.5 | Polymer-3 | 6000 | 0.5 | Tris | 4.5 | — | — | 3.0 | 0.111 | — | 6 | 200 | C | C | C | B |
| | acid | | | | | | | | | | | | | | | | | |
| Example 64 | Citric | 1.5 | Polymer-6 | 6000 | 0.5 | Tris | 4.5 | — | — | 3.0 | 0.111 | — | 6 | 200 | C | C | C | B |
| | acid | | | | | | | | | | | | | | | | | |
| Example 65 | Citric | 1.5 | Polymer-13 | 6000 | 0.5 | Tris | 4.5 | — | — | 3.0 | 0.111 | — | 6 | 200 | B | B | B | B |
| | acid | | | | | | | | | | | | | | | | | |
| Example 66 | Oxalic | 1.5 | Polymer-1b | 6000 | 0.5 | Tris | 4.5 | MIT | 0.05 | 3.0 | 0.111 | 10.0 | 6 | 200 | B | B | B | B |
| | acid | | | | | | | | | | | | | | | | | |
| Example 67 | Malonic | 1.5 | Polymer-1b | 6000 | 0.5 | Tris | 4.5 | MIT | 0.05 | 3.0 | 0.111 | 10.0 | 6 | 200 | B | B | B | B |
| | acid | | | | | | | | | | | | | | | | | |
| Example 68 | Succinic | 1.5 | Polymer-1b | 6000 | 0.5 | Tris | 4.5 | MIT | 0.05 | 3.0 | 0.111 | 10.0 | 6 | 200 | B | B | B | B |
| | acid | | | | | | | | | | | | | | | | | |
| Example 69 | Malic | 1.5 | Polymer-1b | 6000 | 0.5 | Tris | 4.5 | MIT | 0.05 | 3.0 | 0.111 | 10.0 | 6 | 200 | B | B | B | A |
| | acid | | | | | | | | | | | | | | | | | |
| Example 70 | Tartaric | 1.5 | Polymer-1b | 6000 | 0.5 | Tris | 4.5 | MIT | 0.05 | 3.0 | 0.111 | 10.0 | 6 | 200 | B | B | B | A |
| | acid | | | | | | | | | | | | | | | | | |
| Example 71 | Oxalic | 1.5 | Polymer-1b | 6000 | 0.5 | Tris | 4.5 | MIT | 0.05 | 3.0 | 0.111 | 10.0 | 6 | 10 | A | A | A | A |
| | acid | | | | | | | | | | | | | | | | | |
| Example 72 | Malonic | 1.5 | Polymer-1b | 6000 | 0.5 | Tris | 4.5 | MIT | 0.05 | 3.0 | 0.111 | 10.0 | 6 | 10 | A | A | A | A |
| | acid | | | | | | | | | | | | | | | | | |
| Example 73 | Succinic | 1.5 | Polymer-1b | 6000 | 0.5 | Tris | 4.5 | MIT | 0.05 | 3.0 | 0.111 | 10.0 | 6 | 10 | A | A | | A |
| | acid | | | | | | | | | | | | | | | | | |
| Example 74 | Malic | 1.5 | Polymer-1b | 6000 | 0.5 | Tris | 4.5 | MIT | 0.05 | 3.0 | 0.111 | 10.0 | 6 | 10 | A | A | A | A |
| | acid | | | | | | | | | | | | | | | | | |
| Example 75 | Tartaric | 1.5 | Polymer-1b | 6000 | 0.5 | Tris | 4.5 | MIT | 0.05 | 3.0 | 0.111 | 10.0 | 6 | 10 | A | A | A | A |
| | acid | | | | | | | | | | | | | | | | | |
| Example 76 | Oxalic | 1.5 | Polymer-1b | 6000 | 0.5 | Tris | 4.5 | MIT | 0.05 | 3.0 | 0.111 | 10.0 | 6 | 50 | A | A | A | A |
| | acid | | | | | | | | | | | | | | | | | |
| Example 77 | Malonic | 1.5 | Polymer-1b | 6000 | 0.5 | Tris | 4.5 | MIT | 0.05 | 3.0 | 0.111 | 10.0 | 6 | 50 | A | A | A | A |
| | acid | | | | | | | | | | | | | | | | | |
| Example 78 | Succinic | 1.5 | Polymer-1b | 6000 | 0.5 | Tris | 4.5 | MIT | 0.05 | 3.0 | 0.111 | 10.0 | 6 | 50 | A | A | A | A |
| | acid | | | | | | | | | | | | | | | | | |
| Example 79 | Malic | 1.5 | Polymer-1b | 6000 | 0.5 | Tris | 4.5 | MIT | 0.05 | 3.0 | 0.111 | 10.0 | 6 | 50 | A | A | A | A |
| | acid | | | | | | | | | | | | | | | | | |
| Example 80 | Tartaric | 1.5 | Polymer-1b | 6000 | 0.5 | Tris | 4.5 | MIT | 0.05 | 3.0 | 0.111 | 10.0 | 6 | 50 | A | A | A | A |
| | acid | | | | | | | | | | | | | | | | | |
| Example 81 | Oxalic | 1.5 | Polymer-1b | 6000 | 0.5 | Tris | 4.5 | MIT | 0.05 | 3.0 | 0.111 | 10.0 | 6 | 400 | C | C | C | C |
| | acid | | | | | | | | | | | | | | | | | |
| Example 82 | Malonic | 1.5 | Polymer-1b | 6000 | 0.5 | Tris | 4.5 | MIT | 0.05 | 3.0 | 0.111 | 10.0 | 6 | 400 | C | C | C | C |
| | acid | | | | | | | | | | | | | | | | | |
| Example 83 | Succinic | 1.5 | Polymer-1b | 6000 | 0.5 | Tris | 4.5 | MIT | 0.05 | 3.0 | 0.111 | 10.0 | 6 | 400 | C | C | C | C |
| | acid | | | | | | | | | | | | | | | | | |
| Example 84 | Malic | 1.5 | Polymer-1b | 6000 | 0.5 | Tris | 4.5 | MIT | 0.05 | 3.0 | 0.111 | 10.0 | 6 | 400 | C | C | C | B |
| | acid | | | | | | | | | | | | | | | | | |
| Example 85 | Tartaric | 1.5 | Polymer-1b | 6000 | 0.5 | Tris | 4.5 | MIT | 0.05 | 3.0 | 0.111 | 10.0 | 6 | 400 | C | C | C | B |
| | acid | | | | | | | | | | | | | | | | | |
| Example 86 | Citric | 0.25 | Polymer-1b | 6000 | 0.5 | Tris | 4.5 | MIT | 0.05 | 0.5 | 0.111 | 10.0 | 6 | 200 | B | B | B | B |
| | acid | | | | | | | | | | | | | | | | | |
| Example 87 | Citric | 0.5 | Polymer-1b | 6000 | 0.5 | Tris | 4.5 | MIT | 0.05 | 1.0 | 0.111 | 10.0 | 6 | 200 | B | B | B | A |
| | acid | | | | | | | | | | | | | | | | | |
| Example 88 | Citric | 3 | Polymer-1b | 6000 | 0.5 | Tris | 4.5 | MIT | 0.05 | 6.0 | 0.111 | 10.0 | 6 | 200 | B | B | B | A |
| | acid | | | | | | | | | | | | | | | | | |
| Example 89 | Citric | 5 | Polymer-1b | 6000 | 0.5 | Tris | 4.5 | MIT | 0.05 | 10.0 | 0.111 | 10.0 | 6 | 200 | B | B | B | A |
| | acid | | | | | | | | | | | | | | | | | |
| Example 90 | Citric | 10 | Polymer-1b | 6000 | 0.5 | Tris | 4.5 | MIT | 0.05 | 20.0 | 0.111 | 10.0 | 6 | 200 | B | B | B | A |
| | acid | | | | | | | | | | | | | | | | | |

TABLE 4

| | A) Polycarboxylic | | B) Specific | | | C) Amino | | D) Antibacterial | | | | | | | | | | |
|---|---|---|---|---|---|---|---|---|---|---|---|---|---|---|---|---|---|---|
| | acid | | polymer | | | alcohol | | agent | | | | | | Dilution | removability | SiC | SiCN | SiN |
| | | Content | | | Content | | Content | | Content | | | | | ratio | poly-Si | defect | defect | defect |
| | Type | (% by mass) | Type | Mw | (% by mass) | Type | (% by mass) | Type | (% by mass) | A)/B) | B)/C) | B)/D) | pH | (times) | defect | removability | removability | removability |
| Example 91 | Citric | 1.5 | Polymer-1b | 6000 | 0.05 | Tris | 4.5 | MIT | 0.05 | 30.0 | 0.011 | 1.0 | 6 | 200 | B | B | B | A |
| | acid | | | | | | | | | | | | | | | | | |
| Example 92 | Citric | 1.5 | Polymer-1b | 6000 | 0.03 | Tris | 4.5 | MIT | 0.05 | 50.0 | 0.007 | 0.6 | 6 | 200 | B | B | B | B |
| | acid | | | | | | | | | | | | | | | | | |
| Example 93 | Citric | 1.5 | Polymer-1b | 6000 | 0.01 | Tris | 4.5 | MIT | 0.05 | 150.0 | 0.002 | 0.2 | 6 | 200 | C | C | C | C |
| | acid | | | | | | | | | | | | | | | | | |
| Example 94 | Citric | 1.5 | Polymer-1b | 6000 | 1 | Tris | 4.5 | MIT | 0.05 | 1.5 | 0.222 | 20.0 | 6 | 200 | B | B | B | A |
| | acid | | | | | | | | | | | | | | | | | |
| Example 95 | Citric | 1.5 | Polymer-1b | 6000 | 5 | Tris | 4.5 | MIT | 0.05 | 0.3 | 1.111 | 100.0 | 6 | 200 | B | B | B | C |
| | acid | | | | | | | | | | | | | | | | | |
| Example 96 | Citric | 1.5 | Polymer-1b | 6000 | 7.5 | Tris | 4.5 | MIT | 0.05 | 0.2 | 1.667 | 150.0 | 6 | 200 | B | B | B | C |
| | acid | | | | | | | | | | | | | | | | | |
| Example 97 | Citric | 1.5 | Polymer-1b | 6000 | 0.5 | MEA | 4.5 | MIT | 0.05 | 3.0 | 0.111 | 10.0 | 6 | 200 | C | C | C | C |
| | acid | | | | | | | | | | | | | | | | | |
| Example 98 | Citric | 1.5 | Polymer-1b | 6000 | 0.5 | DEA | 4.5 | MIT | 0.05 | 3.0 | 0.111 | 10.0 | 6 | 200 | C | C | C | B |
| | acid | | | | | | | | | | | | | | | | | |
| Example 99 | Citric | 1.5 | Polymer-1b | 6000 | 0.5 | MDEA | 4.5 | MIT | 0.05 | 3.0 | 0.111 | 10.0 | 6 | 200 | C | C | C | B |
| | acid | | | | | | | | | | | | | | | | | |
| Example 100 | Citric | 1.5 | Polymer-1b | 6000 | 0.5 | Bis-Tris | 4.5 | MIT | 0.05 | 3.0 | 0.111 | 10.0 | 6 | 200 | B | B | B | A |
| | acid | | | | | | | | | | | | | | | | | |
| Example 101 | Citric | 1.5 | Polymer-1b | 6000 | 0.5 | Bis-TrisP | 4.5 | MIT | 0.05 | 3.0 | 0.111 | 10.0 | 6 | 200 | B | B | B | A |
| | acid | | | | | | | | | | | | | | | | | |
| Example 102 | Citric | 1.5 | Polymer-1b | 6000 | 0.5 | Tris | 4.5 | Sorbic | 0.05 | 3.0 | 0.111 | 10.0 | 6 | 200 | B | B | B | A |
| | acid | | | | | | | acid | | | | | | | | | | |
| Example 103 | Citric | 1.5 | Polymer-1b | 6000 | 0.5 | Tris | 4.5 | MIT/OIT | 0.05 | 3.0 | 0.111 | 10.0 | 6 | 200 | B | B | B | A |
| | acid | | | | | | | | | | | | | | | | | |
| Example 104 | Citric | 1.5 | Polymer-1b | 6000 | 0.5 | Tris | 4.5 | Cresol | 0.05 | 3.0 | 0.111 | 10.0 | 6 | 200 | B | B | B | A |
| | acid | | | | | | | | | | | | | | | | | |
| Example 105 | Citric | 1.5 | Polymer-1b | 6000 | 0.5 | Tris | 4.5 | Dehydro- | 0.05 | 3.0 | 0.111 | 10.0 | 6 | 200 | B | B | B | A |
| | acid | | | | | | | acetic | | | | | | | | | | |
| | | | | | | | | acid | | | | | | | | | | |
| Example 106 | Citric | 1.5 | Polymer-1b | 6000 | 0.5 | Tris | 4.5 | Benzoic | 0.05 | 3.0 | 0.111 | 10.0 | 6 | 200 | B | B | B | A |
| | acid | | | | | | | acid | | | | | | | | | | |
| Example 107 | Citric | 1.5 | Polymer-1b | 6000 | 0.5 | Tris | 4.5 | Catechol | 0.05 | 3.0 | 0.111 | 10.0 | 6 | 200 | B | B | B | A |
| | acid | | | | | | | | | | | | | | | | | |
| Example 108 | Citric | 1.5 | Polymer-1b | 6000 | 0.5 | Tris | 4.5 | PHMB | 0.05 | 3.0 | 0.111 | 10.0 | 6 | 200 | B | B | B | A |
| | acid | | | | | | | | | | | | | | | | | |
| Example 109 | Citric | 1.5 | Polymer-1b | 6000 | 0.5 | Tris | 4.5 | CHG | 0.05 | 3.0 | 0.111 | 10.0 | 6 | 200 | B | B | B | A |
| | acid | | | | | | | | | | | | | | | | | |
| Example 110 | Citric | 1.5 | Polymer-1b | 6000 | 0.5 | Tris | 1.5 | MIT | 0.05 | 3.0 | 0.333 | 10.0 | 6 | 200 | B | B | B | A |
| | acid | | | | | | | | | | | | | | | | | |
| Example 111 | Citric | 1.5 | Polymer-1b | 6000 | 0.5 | Tris | 0.3 | MIT | 0.05 | 3.0 | 1.667 | 10.0 | 6 | 200 | C | C | C | B |
| | acid | | | | | | | | | | | | | | | | | |
| Example 112 | Citric | 1.5 | Polymer-1b | 6000 | 1 | Tris | 4.5 | MIT | 0.25 | 1.5 | 0.222 | 4.0 | 6 | 200 | B | B | B | A |
| | acid | | | | | | | | | | | | | | | | | |
| Example 113 | Citric | 1.5 | Polymer-1b | 6000 | 0.5 | Tris | 1.5 | MIT | 0.5 | 3.0 | 0.333 | 1.0 | 6 | 200 | B | B | B | A |
| | acid | | | | | | | | | | | | | | | | | |
| Example 114 | Citric | 1.5 | Polymer-1b | 6000 | 1 | Tris | 4.5 | MIT | 0.01 | 1.5 | 0.222 | 100.0 | 6 | 200 | B | B | B | C |
| | acid | | | | | | | | | | | | | | | | | |
| Example 115 | Citric | 1.5 | Polymer-1b | 6000 | 1 | Tris | 4.5 | MIT | 0.005 | 1.5 | 0.222 | 200.0 | 6 | 200 | B | B | B | C |
| Example 100 | acid | | | | | | | | | | | | | | | | | |
| Comparative | Citric | 1.5 | — | — | — | Tris | 4.5 | MIT | 0.05 | — | — | — | 6 | 200 | E | E | E | E |
| Example 1 | acid | | | | | | | | | | | | | | | | | |
| Comparative | Citric | 1.5 | Polyacrylic | 6000 | 0.5 | Tris | 4.5 | MIT | 0.05 | — | — | — | 6 | 200 | E | E | E | A |
| Example 2 | acid | | acid | | | | | | | | | | | | | | | |
| Comparative | Citric | 1.5 | Polyacryl- | 6000 | 0.5 | Tris | 4.5 | MIT | 0.05 | — | — | — | 6 | 200 | E | E | E | E |
| Example 3 | acid | | amide | | | | | | | | | | | | | | | |

From the results in the tables, it was found that the treatment liquids of Examples of the present invention had excellent defect removability on poly-Si, SiC, or SiCN.

On the other hand, the treatment liquids of Comparative Examples, which did not contain the specific polymer, did not exhibit sufficient defect removability on poly-Si, SiC, or SiCN.

It was found that, in a case where the weight-average molecular weight of the specific polymer was 1,000 to 50,000, the effect of the present invention and the defect removability on SiN were more excellent; and in a case where the weight-average molecular weight of the specific polymer was 1,000 to 20,000, the effect of the present invention and the defect removability on SiN were further excellent (comparison of Example 6, Example 28, and Examples 31 to 33).

It was found that, in a case where the nonionic monomer in the specific polymer had an aliphatic hydrocarbon group, the effect of the present invention was more excellent (comparison of Examples 34 to 47, and the like).

It was found that, in a case where the polycarboxylic acid had a hydroxyl group, the defect removability on SiN was more excellent (comparison of Example 6 and Examples 66 to 70).

It was found that, in a case where the mass ratio of the content of the polycarboxylic acid to the content of the polymer was 0.2 to 50, at least one of the effect of the present invention or the defect removability on SiN was more excellent; and in a case where the mass ratio was 1 to 30, the defect removability on SiN was more excellent (comparison of Example 6 and Examples 91 to 96, and the like).

It was found that, in a case where the number of hydroxyl groups in the amino alcohol was 2 or more, the defect removability on SiN was more excellent; and in a case where the number of hydroxyl groups in the amino alcohol was 3 or more, the effect of the present invention was more excellent (comparison of Examples 97 to 101).

It was found that, in a case where the mass ratio of the content of the polymer to the content of the amino alcohol was 0.005 to 0.5, the effect of the present invention and the defect removability on SiN were more excellent (comparison of Examples 91 to 96, and the like).

It was found that, in a case where the mass ratio of the content of the polymer to the content of the antibacterial agent was 1.0 to 20.0, the defect removability on SiN was more excellent (comparison of Examples 91 to 96, and the like).

It was found that, even in a case where the copolymerization ratio of the specific polymer used in each example was changed from 50/50 to a range of 25/75 to 55/45, in the above-described evaluation test for the defect removability, the same evaluation results as those of the treatment liquid of each example were obtained.

In the above-described evaluation test for the defect removability, the object (wafer with poly-Si, wafer with SiC, wafer with SiCN, or wafer with SiN) after the CMP treatment was used, and a surface of the wafer which had been further polished was subjected to a buffing treatment.

In the buffing treatment, the treatment liquids of Examples 4 to 8 and 66 to 70, which were adjusted to room temperature (23° C.), were used as a composition for the buffing treatment. In addition, using the above-described polishing device used in the CMP treatment, a buffing treatment was performed under conditions of a polishing pressure: 2.0 psi, a supply rate of the composition for the buffing treatment: 250 mL/min, and a polishing time: 60 seconds.

Thereafter, the wafer subjected to the buffing treatment was cleaned over 30 seconds using each of the treatment liquids of Examples 4 to 8 and 66 to 70, which had been adjusted to room temperature (23° C.), and then subjected to a drying treatment. The same treatment liquid was used as the treatment liquid used in the buffing treatment and the treatment liquid used in the cleaning.

As a result of evaluating cleaning performance of the treatment liquid with respect to the polished surface of the obtained wafer according to the evaluation test method for [Defect removability] described above, it was found that the defect removability on poly-Si, SiC, or SiCN exhibited evaluation results one stage higher than the evaluation results of each example described in the tables in a case where each treatment liquid was used. For example, in the tables, all the evaluations of the defect removability on poly-Si, SiC, or SiCN of Example 4 were B, but in a case where the treatment liquid of Example 4 was used in the buffing treatment and the subsequent cleaning treatment, all the evaluations of the defect removability on poly-Si, SiC, or SiCN were A.

What is claimed is:

1. A treatment liquid for manufacturing a semiconductor, comprising:
a polycarboxylic acid; and
a polymer including a repeating unit A derived from a nonionic monomer and a repeating unit B having an anionic group.

2. The treatment liquid for manufacturing a semiconductor according to claim 1,
wherein the repeating unit A is a repeating unit represented by Formula (1), 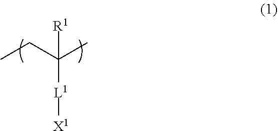
in Formula (1), R¹ represents a hydrogen atom or an alkyl group,
L¹ represents a single bond, —COO—, or —CO—NR^{a}—, and
X¹ represents a hydrogen atom, a hydrocarbon group, or a group including a polymer chain, where a methylene group in the hydrocarbon group may be substituted with —CO— or —O—,
provided that, in a case where X¹ is a hydrogen atom, L¹ represents —CO—NR^{a}—, and R^{a} represents a hydrogen atom or an alkyl group.

3. The treatment liquid for manufacturing a semiconductor according to claim 2,
wherein L¹ represents —COO— or —CO—NR^{a}—.

4. The treatment liquid for manufacturing a semiconductor according to claim 1,
wherein a C log P of the nonionic monomer is-1.00 to 5.00.

5. The treatment liquid for manufacturing a semiconductor according to claim 1,
wherein the repeating unit B is a repeating unit represented by Formula (2), 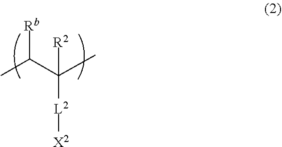
in Formula (2), Rb represents a hydrogen atom or an anionic group,
R² represents a hydrogen atom or an alkyl group,
L² represents a single bond or a divalent linking group, and
X² represents an anionic group.

6. The treatment liquid for manufacturing a semiconductor according to claim 5,
wherein the anionic group is a carboxylic acid group, a sulfonic acid group, or a phosphonic acid group.

7. The treatment liquid for manufacturing a semiconductor according to claim 1,
wherein the polycarboxylic acid has a hydroxyl group.

8. The treatment liquid for manufacturing a semiconductor according to claim 1,
wherein a weight-average molecular weight of the polymer is 1,000 to 50,000.

9. The treatment liquid for manufacturing a semiconductor according to claim 1,
wherein a mass ratio of a content of the polycarboxylic acid to a content of the polymer is 1 to 30.

10. The treatment liquid for manufacturing a semiconductor according to claim 1,
wherein a pH is 2.0 to 10.0.

11. The treatment liquid for manufacturing a semiconductor according to claim 1, further comprising:
an amino alcohol.

12. The treatment liquid for manufacturing a semiconductor according to claim 11,
wherein the number of hydroxyl groups in the amino alcohol is 2 or more.

13. The treatment liquid for manufacturing a semiconductor according to claim 11,
wherein a mass ratio of a content of the polymer to a content of the amino alcohol is 0.005 to 0.5.

14. The treatment liquid for manufacturing a semiconductor according to claim 1, further comprising:
an antibacterial agent.

15. The treatment liquid for manufacturing a semiconductor according to claim 14,
wherein a mass ratio of a content of the polymer to a content of the antibacterial agent is 0.1 to 200.

16. The treatment liquid for manufacturing a semiconductor according to claim 1,
wherein the treatment liquid is used for an object to be treated, containing at least one selected from the group consisting of polysilicon, silicon carbide, and silicon carbonitride.

17. The treatment liquid for manufacturing a semiconductor according to claim 2,
wherein the treatment liquid is used for an object to be treated, containing at least one selected from the group consisting of polysilicon, silicon carbide, and silicon carbonitride.

18. The treatment liquid for manufacturing a semiconductor according to claim 3,
wherein the treatment liquid is used for an object to be treated, containing at least one selected from the group consisting of polysilicon, silicon carbide, and silicon carbonitride.

19. A cleaning method of an object to be treated, comprising:
a step of cleaning an object to be treated, containing at least one selected from the group consisting of polysilicon, silicon carbide, and silicon carbonitride, with the treatment liquid for manufacturing a semiconductor according to claim 1.

20. A manufacturing method of a semiconductor, comprising:
the cleaning method of an object to be treated according to claim 19.
